(19) United States
(12) Patent Application Publication
(10) Pub. No.: US 2026/0214885 A1
(43) Pub. Date: Jul. 23, 2026

(54) SEMICONDUCTOR DEVICE INCLUDING A MEMORY ARRAY AND METHODS OF FORMATION

(71) Applicant: Taiwan Semiconductor Manufacturing Company, Ltd., Hsinchu (TW)

(72) Inventors: Chih-Yu CHANG, New Taipei City (TW); Kuo-Chang CHIANG, Hsinchu City (TW); Chieh-Fang CHEN, Hsinchu (TW); Katherine H. CHIANG, New Taipei City (TW)

(73) Assignee: Taiwan Semiconductor Manufacturing Company, Ltd., Hsinchu (TW)

(21) Appl. No.: 19/034,991

(22) Filed: Jan. 23, 2025

(51) Int. Cl. H10B 12/00

(52) U.S. Cl. CPC H10B 12/482; H10B 12/033; H10B 12/0387; H10B 12/05; H10B 12/315; H10B 12/488

(57) ABSTRACT

Memory cell structures of a memory array are formed using materials and processes that are compatible with complementary metal-oxide-semiconductor (CMOS) integrated circuits that have been formed on a semiconductor device. In particular, the transistor structures of the memory cell structures are formed to include oxide-semiconductor channel layers as opposed to semiconductor channel layers. The oxide-semiconductor channel layers may be formed by lower-temperature processes (e.g., chemical vapor deposition (CVD)) relative to semiconductor channel layers (e.g., epitaxial growth). Thus, the formation of the oxide-semiconductor channel layers is less likely to degrade and/or damage the layers and/or structures of the CMOS integrated circuits of the semiconductor device. In this way, the semiconductor device may be formed monolithically, meaning the memory array may be formed above the device layer of the semiconductor device in which the CMOS integrated circuits were formed.

### BACKGROUND

In some cases, a non-volatile memory cell may include a transistor (or transistor gate) connected in series with a memory structure such as a capacitor, a phase change material layer, a resistive layer, and/or a magnetic layer, among other examples. This may be referred to as a one transistor—one memory structure (1T-1X) cell. The memory structure in a 1T-1X cell selectively stores data (e.g., a logical “1” value or a logical “0” value) based on an electric charge, a resistivity, an electric polarity, and/or a magnetic polarity, among other examples. The state of the memory structure may be selectively modified and/or read by using the transistor to provide or block access to the memory element.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor device described herein.

FIG. 2 is a diagram of an example implementation of a memory array described herein.

FIGS. 3A-3D are diagrams of an example implementation of forming a semiconductor device described herein.

FIGS. 4A-4O are diagrams of an example implementation of forming a memory array described herein.

FIG. 5 is a diagram of an example implementation of a memory array described herein.

FIGS. 6A-6P are diagrams of an example implementation of forming a memory array described herein.

FIG. 7 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a memory array that includes a plurality of memory cell structures (e.g., 1T-1X memory cell structures and/or another type of memory cell structures) may be integrated into a semiconductor device along with complementary metal-oxide-semiconductor (CMOS) integrated circuits. The memory array may be vertically arranged in the semiconductor with a device layer that includes the CMOS integrated circuits so that the device layer and the memory array are stacked in a three-dimensional (3D) integrated circuit (3DIC) arrangement in the semiconductor device.

While stacking the memory array and the device layers facilitates 3D integration of the CMOS integrated circuits with the memory array, the manufacturing processes for forming the memory array may be incompatible with the CMOS integrated circuits. For example, the memory cell structures may include layers and/or structures that are formed using high-temperature processing, and this high-temperature processing may degrade or even damage layers and/or structures of the CMOS integrated circuits.

In some implementations described herein, memory cell structures of a memory array are formed using materials and processes that are compatible with CMOS integrated circuits that have been formed on a semiconductor device. In particular, the transistor structures of the memory cell structures are formed to include oxide-semiconductor channel layers as opposed to semiconductor channel layers. The oxide-semiconductor channel layers may be formed by lower-temperature processes (e.g., chemical vapor deposition (CVD)) relative to semiconductor channel layers (e.g., epitaxial growth). Thus, the formation of the oxide-semiconductor channel layers is less likely to degrade and/or damage the layers and/or structures of the CMOS integrated circuits of the semiconductor device. In this way, the semiconductor device may be formed monolithically, meaning the memory array may be formed above the device layer of the semiconductor device in which the CMOS integrated circuits were formed (e.g., as opposed to forming the device layer and the memory array on separate dies and bonding the dies together).

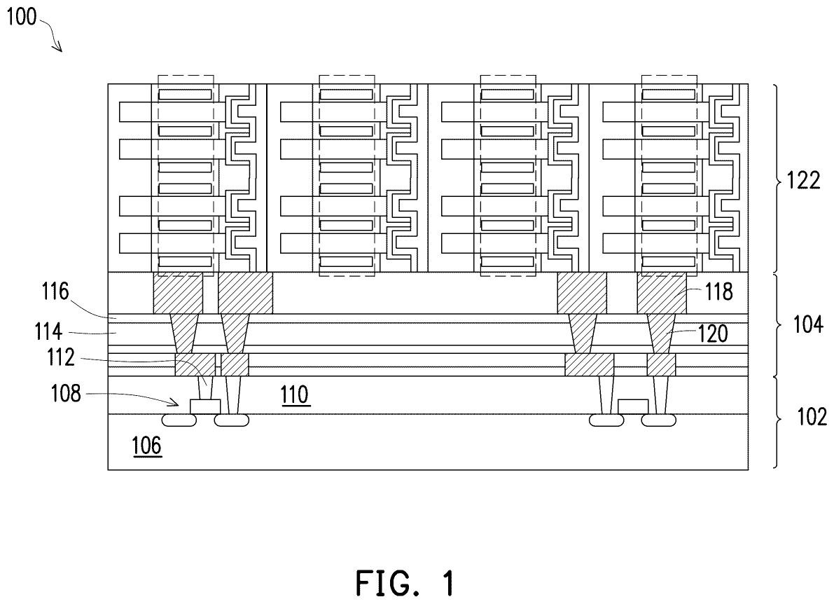

FIG. 1 is a diagram of an example semiconductor device 100 described herein. The semiconductor device 100 may include a system on chip (SoC) device, a logic device such as a central processing unit (CPU) or a graphics processing unit (GPU), a memory device (e.g., a high bandwidth memory (HBM) device), an image sensor device (e.g., a complementary metal-oxide-semiconductor (CMOS) image sensor device), and/or another type of semiconductor device.

FIG. 1 illustrates a cross-section view of the semiconductor device 100. As shown in FIG. 1, the semiconductor device 100 may include a device layer 102 and an interconnect layer 104 arranged in a z-direction in the semiconductor device 100 the device layer 102. For example, the interconnect layer 104 may be located above the device layer 102. As another example, the interconnect layer 104 may be located below the device layer 102.

The interconnect layer 104 may include conductive structures that are arranged to carry signals and/or provide power distribution throughout the semiconductor device 100. In some implementations, the semiconductor device 100 includes interconnect layers 104 above and below the device layer 102. A first interconnect layer 104 on a first side of the device layer 102 may be used for signal propagation throughout the semiconductor device 100, and a second interconnect layer 104 on an opposing second side of the device layer 102 may be used for power distribution in the semiconductor device 100.

The device layer 102 includes a substrate 106 of the semiconductor device 100. The substrate 106 may correspond to a portion of a semiconductor wafer on which the semiconductor device 100 is formed. The substrate 106 may include a silicon (Si) substrate, a substrate formed of a material including silicon, a III-V compound semiconductor material substrate such as gallium arsenide (GaAs), a silicon on insulator (SOI) substrate, or another type of substrate. The substrate 106 may extend in an x-direction and/or in a y-direction in the semiconductor device 100 such that the top and bottom surfaces of the substrate 106 are approximately orthogonal to the z-direction in the semiconductor device 100.

Integrated circuit devices 108 may be included in and/or on the substrate 106 in the device layer 102 of the semiconductor device 100. The integrated circuit devices 108 may include front end transistor structures (e.g., front end planar transistor structures, front end fin field effect transistor (finFET) structures, front end gate all around (GAA) transistor structures), pixel sensors, capacitors, resistors, inductors, photodetectors, transceivers, transmitters, receives, optical circuits, and/or other types of front end semiconductor devices.

A front end transistor structure may include a plurality of source/drain regions, which may correspond to doped regions of the substrate 106, separated by a channel region in the substrate 106. In some implementations, the source/drain regions are doped with a first type of dopant (e.g., a p-type dopant such as boron (B) and/or gallium (Ga), an n-type dopant such as phosphorous (P) and/or arsenic (As)), and the channel region is doped with a second type of dopant that is different from the first type of dopant. The front end transistor structure may include a gate structure over and/or around the channel region. A gate dielectric layer of the front end transistor structure may be included between the gate structure and the channel region. The gate structure may include a polysilicon gate, a metal gate with a high dielectric constant (high-k) gate dielectric layer such as hafnium oxide (HfOₓ such as HfO₂), and/or another type of gate structure.

A dielectric layer 110 is included over the substrate 106. The dielectric layer 110 includes an interlayer dielectric (ILD) layer, an etch stop layer (ESL), and/or another type of dielectric layer. The dielectric layer 110 includes dielectric material(s) that enable various portions of the substrate 106 and/or the integrated circuit devices 108 to be selectively etched or protected from etching, and/or to electrically isolate the integrated circuit devices 108 in the device layer 102. The dielectric layer 110 includes a silicon nitride (SiₓN_{y}), an oxide (e.g., a silicon oxide (SiOₓ) and/or another oxide material), and/or another type of dielectric material. The dielectric layer 110 may extend in the x-direction and/or in the y-direction in the semiconductor device 100. Contacts 112 (e.g., source/drain contacts, gate contacts) may extend through the dielectric layer 110 and between the integrated circuit devices 108 and the interconnect layer 104. The contacts may electrically connect the integrated circuit devices 108 to the interconnect layer 104. The contacts 112 may include vias, plugs, and/or another type of elongated electrically conductive structures. The contacts 112 may include tungsten (W), cobalt (Co), ruthenium (Ru), titanium (Ti), aluminum (Al), and/or gold (Au), among other electrically conductive materials.

The interconnect layer 104 includes a plurality of dielectric layers (e.g., back end dielectric layers) that are arranged in a direction (e.g., the z-direction) that is approximately perpendicular to the top surface of the substrate 106. The dielectric layers may include ILD layers 114 and ESLs 116 that are arranged in an alternating manner in the z-direction. The ILD layers 114 and the ESLs 116 may extend in the x-direction and/or in the y-direction in the semiconductor device 100.

The ILD layers 114 may each include a low dielectric constant (low-k) oxide material such as silicon oxide (SiOₓ) or undoped silicate glass (USG). Additionally and/or alternatively, the ILD layers 114 may each include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 114 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (α-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples.

The ESLs 116 may each include a silicon nitride (SiₓN_{y}), silicon carbide (SiC), silicon oxynitride (SiON), silicon carbonitride (SiCN), silicon oxycarbonitride (SiCON), and/or another suitable dielectric material. In some implementations, an ILD layer 114 and an ESL 116 may include different dielectric materials to provide etch selectivity to enable various structures to be formed in the interconnect layer 104. For example, the ILD layers 114 may each include a low-k

dielectric material such as silicon oxide (SiOₓ) or USG, and the ESLs 116 may each include a high-k dielectric material such as silicon nitride (SiₓN_{y}) or silicon carbide (SiC). In some implementations, one or more of the ESLs 116 may include the same or similar materials as one or more of the ILD layers 114.

The interconnect layer 104 includes a plurality of conductive structures that are arranged in a plurality of layers. The conductive structures may be electrically coupled and/or physically coupled with one or more of the integrated circuit devices 108 in the device layer 102. The conductive structures provide electrical routing that enables signals and/or power to be provided to and/or from the integrated circuit devices 108. The layers of conductive structures may include a plurality of layers of metallization structures 118, and a plurality of the layers of interconnect structures 120.

The layers of metallization structures 118 may be referred to as M-layers. For example, a layer of metallization structures 118 (referred to as a metal-0 (M0) layer) may be located at the bottom of the interconnect layer 104 and may be coupled with the device layer 102. In particular, the metallization structures 118 in the M0 layer may be coupled with the contacts 112 (e.g., a contact layer referred to as “CO” layer) of the integrated circuit devices 108 in the device layer 102. A layer of metallization structures 118 (referred to as a metal-1 layer (M1) layer) may be located above the M0 layer of metallization structures 118 in the interconnect layer 104, a layer of metallization structures 118 (referred to as a metal-2 layer (M2) layer) may be located above the M1 layer of metallization structures 118, and so on.

A layer of interconnect structures 120 (referred to as a via-1 (V0) layer) may be included between the M0 layer and the M1 layer to interconnect the M0 layer and the M1 layer, a layer of interconnect structures 120 (referred to as a via-2 (V1) layer) may be included between the M1 layer and the M2 layer to interconnect the M1 layer and the M2 layer, and so on.

The metallization structures 118 may include a combination of trenches, metallization layers, conductive traces, and/or other types of conductive structures. The interconnect structures 120 may include a combination of vias, interconnects, and/or other types of conductive structures. The metallization structures 118 and the interconnect structures 120 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner

layers are included between the dielectric layers of the interconnect layer 104 and the metallization structures 118, and/or between the dielectric layers of the interconnect layer 104 the interconnect structures 120. The one or more liner layers may include barrier liners, adhesion liners, and/or another type of liners. Examples of materials for the one or more liners include tantalum nitride (TaN) and/or titanium nitride (TiN), among other examples.

As further shown in FIG. 1, a memory array 122 is included above the device layer 102 so that the device layer 102 and the memory array 122 are stacked and vertically arranged in the semiconductor device 100. In some implementations, the interconnect layer 104 is included vertically between the device layer 102 and the memory array 122. In some implementations, the interconnect layer 104 is omitted, and the memory array 122 is included directly on the device layer 102.

The memory array 122 includes a plurality of memory cell structures that are interconnected in an array. The memory array 122 may be configured to store data in the semiconductor device 100. In some implementations, the metallization structures 118 and the interconnect structures 120 in the interconnect layer 104 electrically connect the memory cell structures of the memory array 122 to the integrated circuit devices 108 in the device layer 102.

As indicated above, FIG. 1 is provided as an example. Other examples may differ from what is described with regard to FIG. 1.

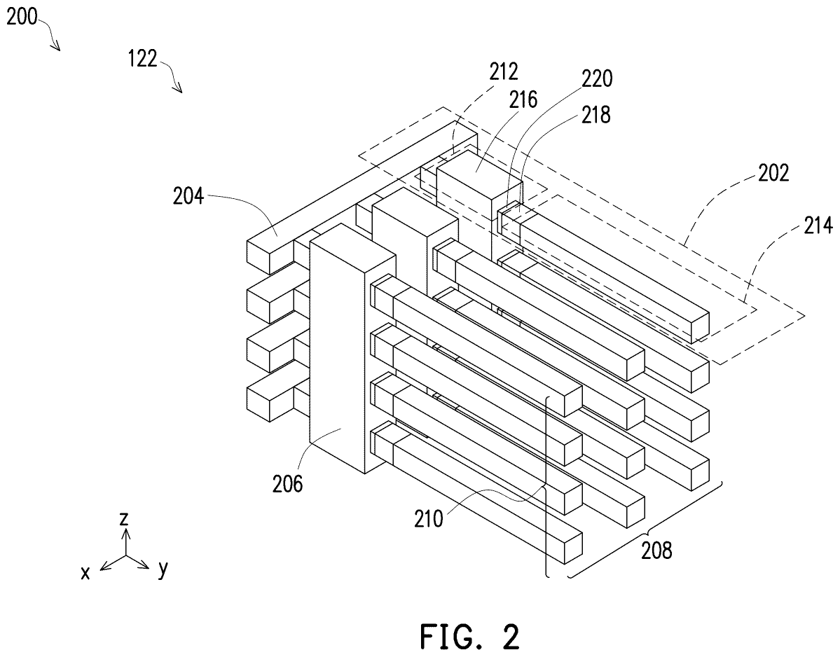

FIG. 2 is a diagram of an example implementation 200 of a memory array 122 described herein. The example implementation 200 of the memory array 122 illustrated in FIG. 2 may be included above the device layer 102 and the interconnect layer 104 of the semiconductor device 100. Thus, the device layer 102, the interconnect layer 104, and the memory array 122 may be stacked and vertically arranged (e.g., in the z-direction) in the semiconductor device 100.

As shown in FIG. 2, the memory array 122 includes a plurality of memory cell structures 202. The memory cell structures 202 may be arranged in a grid in an x-direction (e.g., a lateral direction) and in a z-direction (e.g., a vertical direction) in the memory array 122, and may be electrically interconnected by bit line conductive structures 204 and word line conductive structures 206 of the memory array 122.

The memory array 122 may include a plurality of rows 208 of memory cell structures 202 and a plurality of columns 210 of memory cell structures 202. The rows 208 of memory cell structures 202 may be arranged in the z-direction (e.g., a vertical direction that is approximately

perpendicular to the device layer 102 of the semiconductor device 100), and the memory cell structures 202 in a row 208 may be arranged in the x-direction (e.g., a lateral direction that is approximately perpendicular to the z-direction). The columns 210 of memory cell structures 202 may be arranged in the x-direction (e.g., a lateral direction that is approximately parallel to the device layer 102 of the semiconductor device 100), and the memory cell structures 202 in a column 210 may be arranged in the z-direction (e.g., a vertical direction that is approximately perpendicular to the x-direction).

Each memory cell structure 202 in the memory array 122 may be located at an intersection between a row 208 and a column 210. The rows 208 and the columns 210 of memory cell structure 202 may be electrically interconnected by bit line conductive structures 204 and word line conductive structures 206 of the memory array 122. In some implementations, the bit line conductive structures 204 and/or the word line conductive structures 206 may be connected to metallization structures 118 and/or to interconnect structures 120 in the interconnect layer 104 of the semiconductor device 100. In some implementations, the bit line conductive structures 204 and/or the word line conductive structures 206 may be connected to the integrated circuit devices 108 (e.g., directly and/or through metallization structures 118 and/or to interconnect structures 120 in the interconnect layer 104 of the semiconductor device 100) in the device layer 102 of the semiconductor device 100.

The bit line conductive structures 204 of memory array 122 may be arranged in the z-direction (e.g., a vertical direction that is approximately perpendicular to the device layer 102 of the semiconductor device 100), and may be elongated and may extend in the x-direction (e.g., a lateral direction that is approximately perpendicular to the z-direction). Thus, the memory array 122 may be referred to as a lateral bit line array or a horizontal bit line array. The memory cell structures 202 in a row 208 may be connected to the same bit line conductive structure 204, and each row 208 of memory cell structures 202 may be connected to a respective bit line conductive structure 204.

The word line conductive structures 206 of memory array 122 may be arranged in the x-direction (e.g., a lateral direction that is approximately parallel to the device layer 102 of the semiconductor device 100), and may be elongated and may extend in the z-direction (e.g., a vertical direction that is approximately perpendicular to the x-direction). Thus, the memory array 122 may be referred to as a vertical word line array. The memory cell structures 202 in a column 210 may be connected to the same word line conductive structure 206, and each column 210 of memory cell structures 202 may be connected to a respective word line conductive structure 206.

A memory cell structure 202 may be a 1T-1X memory cell that includes a transistor structure 212 that is electrically coupled to a memory structure 214. The transistor structure 212 of a memory cell structure 202 may be located laterally adjacent to the memory structure 214 of the memory cell structure 202 in the y-direction in the memory array 122. Thus, the memory cell structures 202 may be elongated in, and may extend in, the y-direction in the semiconductor device 100.

The transistor structure 212 of a memory cell structure 202 may be electrically coupled and/or physically coupled to a bit line conductive structure 204 and a word line conductive structure 206. The transistor structure 212 may be configured to selectively activate and provide access to the associated memory structure 214 of the memory cell structure 202 so that one or more types of memory operations may be performed for the memory cell structure 202. Examples of such memory operations include a write operation (or program operation) (e.g., in which the memory structure 214 is programmed to store a particular logical value), a read operation (e.g., in which the logical value is read from the memory structure 214), and/or an erase operation (e.g., in which the logical value is erased from the memory structure 214).

The memory structures 214 may extend primarily in the y-direction (e.g., in a lateral direction) in the memory array 122. The memory structure 214 of a memory cell structure 202 may include a capacitor structure (e.g., a deep trench capacitor (DTC) structure, a thin film capacitor structure), a ferroelectric storage structure, a magnetic storage structure, a resistive storage structure, a phase change material storage structure, and/or another type of storage structure that is capable of being configured in two or more states corresponding to or more logical values. For example, a first state (e.g., a first charge magnitude, a first polarity, a first resistance) may correspond to a “0” logical value, and a second state (e.g., a second charge magnitude, a second polarity, a second resistance) may correspond to a “1” logical value. In some implementations, a memory structure 214 may be configured with greater than two candidate states.

The transistor structure 212 of a memory cell structure 202 may include a gate structure 216 that wraps around two or more sides of an oxide-semiconductor channel layer 218 of the transistor structure 212, and a gate dielectric layer 220 between the gate structure 216 and the oxide-semiconductor channel layer 218. In some implementations, the gate structure 216 and the gate dielectric layer 220 both laterally wrap around at least three sides of the oxide-semiconductor channel layer 218, thereby providing greater gate control over the conductivity of the oxide-semiconductor channel layer 218. In some implementations, the gate structure 216 and the gate dielectric layer 220 both entirely laterally wrap around all sides of the oxide-semiconductor channel layer 218, which provides further gate control over the conductivity of the oxide-semiconductor channel layer 218.

The gate structure 216 of a transistor structure 212 of a memory cell structure 202 may be a metal gate structure that includes one or more metal materials. Examples of such materials include copper (Cu), cobalt (Co), ruthenium (Ru), titanium (Ti), tungsten (W), and/or aluminum (Al), tantalum nitride (TaN), titanium nitride (TiN), and/or another metal material. A gate structure 216 of a transistor structure 212 of a memory cell structure 202 may correspond to a portion of a word line conductive structure 206 that wraps around the oxide-semiconductor channel layer 218 of the transistor structure 212. Thus, the gate structures 216 of the transistor structures 212 of the memory cells structures 202 may be electrically coupled and/or physically coupled to the word line conductive structures 206.

The gate dielectric layer 220 of a transistor structure 212 of a memory cell structure 202 may include one or more dielectric materials. In some implementations, a gate dielectric layer 220 includes one or more low dielectric constant (low-k) dielectric materials (e.g., a dielectric material having a dielectric constant of approximately 3.9 or less), such as a silicon oxide (SiOₓ such as SiO₂), undoped silicate glass (USG), and/or fluoride-doped silicate glass (FSG), among other examples. In some implementations, a gate dielectric layer 220 includes one or more high dielectric constant (high-k) dielectric materials (e.g., a dielectric material having a dielectric constant of greater than approximately 3.9), such as a silicon nitride (SiₓN_{y} such as Si₃N₄), a silicon oxynitride (SiON), a hafnium oxide (HfOₓ such as HfO₂), an aluminum oxide (AlₓO_{y} such as Al₂O₃), a lanthanum oxide (LaₓO_{y} such as La₂O₃), zirconium oxide (ZrOₓ such as ZrO₂), and/or an yttrium oxide (YₓO_{y} such as Y₂O₃), among other examples.

The oxide-semiconductor channel layers 218 of the transistor structures 212 of the memory cell structures 202 may extend laterally in the y-direction in the memory array 122. A first end of an oxide-semiconductor channel layer 218 of a transistor structure 212 of a memory cell structure 202 may be electrically coupled and/or physically coupled to a bit line conductive structure 204. A second end of the oxide-semiconductor channel layer 218 opposing the first end may be electrically coupled and/or physically coupled to a memory structure 214 of the memory cell structure 202.

In some implementations, the portions of an oxide-semiconductor channel layer 218 of a transistor structure 212 that extend laterally outward from an associated gate structure 216 of the transistor structure 212 are referred to as source/drain regions of the transistor structure 212. “Source/drain region” may refer to a source region or a drain region, individually or collectively, depending upon the context.

The oxide-semiconductor channel layers 218 may each include an oxide-semiconductor material. Thus, the transistor structures 212 of the memory cell structures 202 may be referred to as oxide-semiconductor field effect transistors (OSFETs). In some implementations, an oxide-semiconductor channel layer 218 includes an n-type oxide-semiconductor material such as indium gallium zinc oxide (InGaZnO or IGZO), zinc oxide (ZnO), indium oxide (InₓO_{y} such as In₂O₃), tin dioxide (SnO₂), among other examples. In some implementations, an oxide-semiconductor channel layer 218 includes a p-type oxide-semiconductor material such as nickel oxide (NiO), copper oxide (CuₓO such as Cu₂O), copper aluminum oxide (CuAlOₓ such as CuAlO₂), copper gallium oxide (CuGaOₓ such as CuGaO₂), copper indium oxide (CuInOₓ such as CuInO₂), strontium copper oxide (SrCuₓO_{y} such as SrCu₂O₂), and/or tin oxide (SnO), among other examples.

A gate structure 216 of a transistor structure 212 of a memory cell structure 202 may selectively control the electrical conductivity of an oxide-semiconductor channel layer 218 of the transistor structure 212. For example, a gate voltage may be applied to the gate structure 216 through an associated word line conductive structure 206 to activate the transistor structure 212. This enables charge carriers to flow through oxide-semiconductor channel layer 218 between an associated bit line conductive structure 204 and a memory structure 214 of the memory cell structure 202. This enables data to be stored in the memory structure 214, read from the memory structure 214, and/or erased from the memory structure 214.

The oxide-semiconductor channel layers 218 of the transistor structures 212 of the memory cell structures 202 may be formed using low-temperature deposition processes such as chemical vapor deposition (CVD). These processes may be performed at temperatures that are

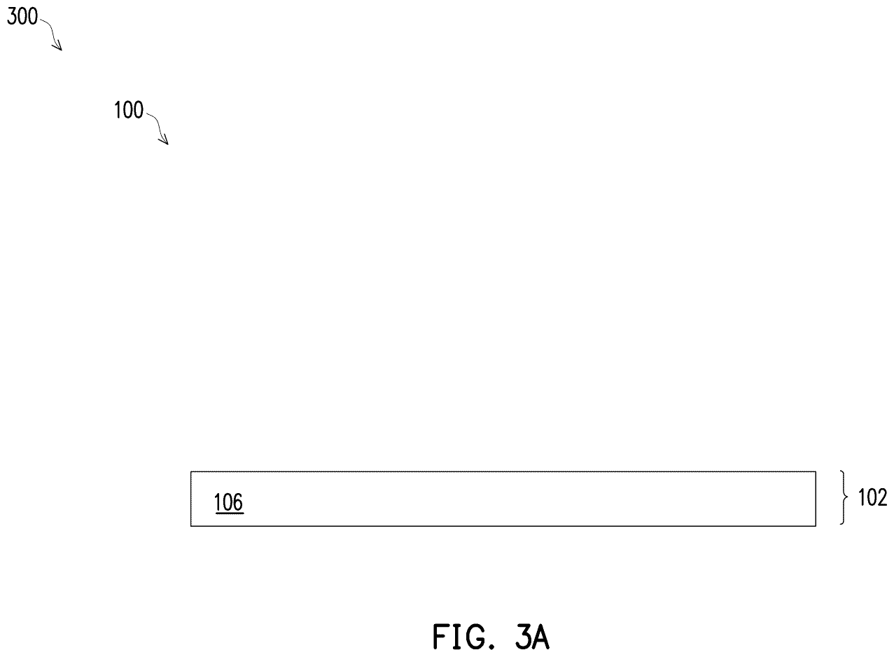

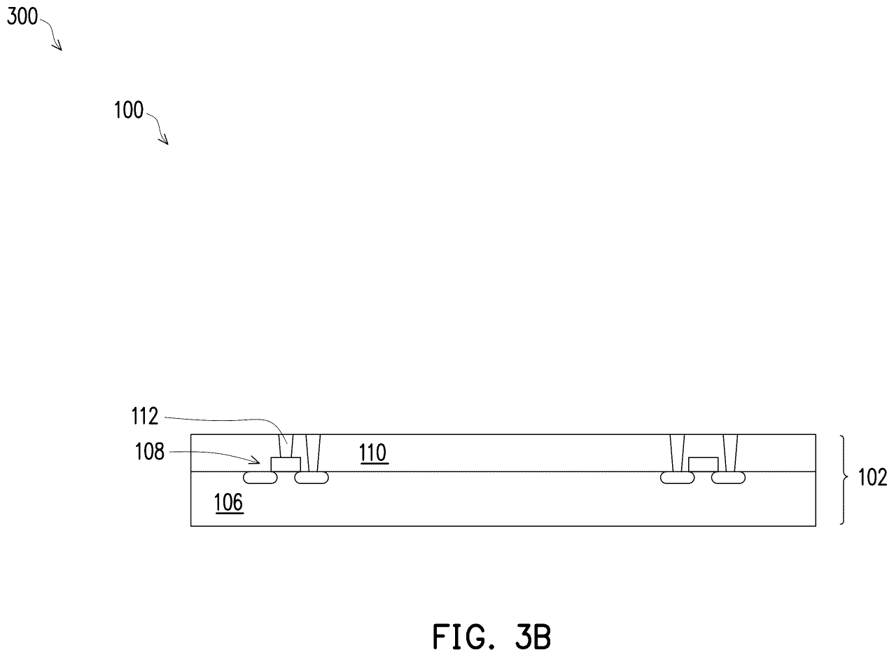

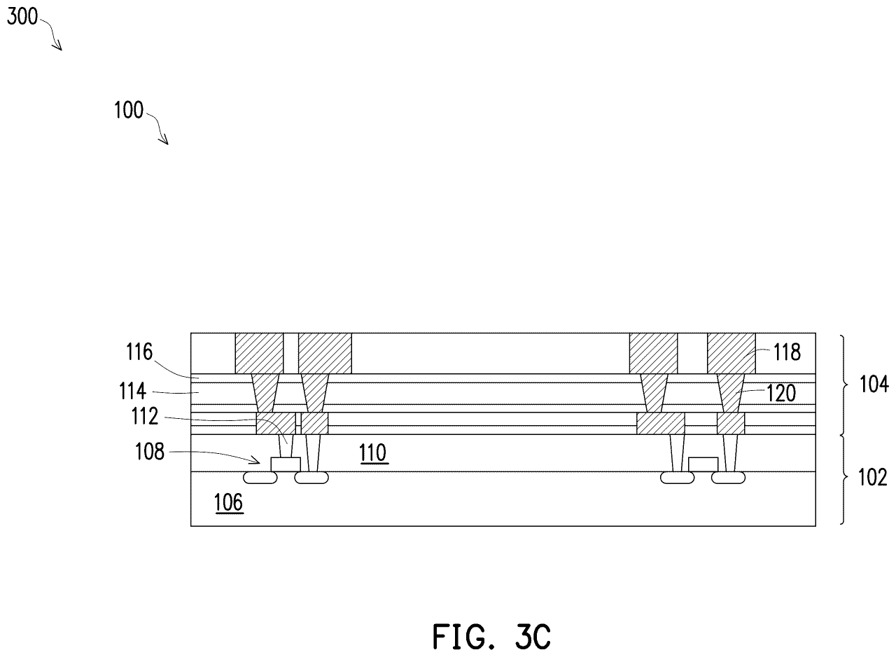

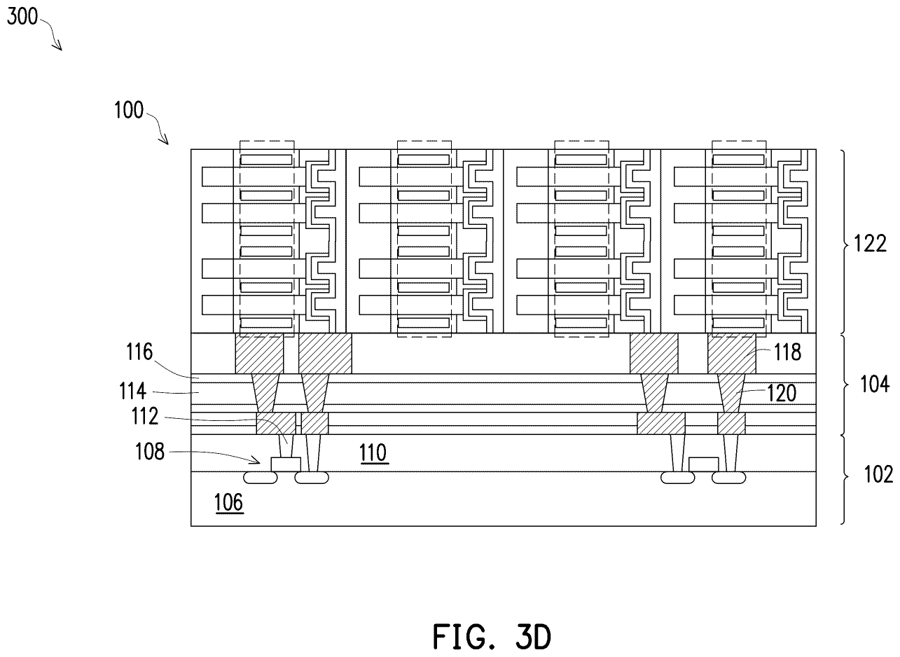

lower than the temperatures for forming semiconductor channel layers by epitaxy, such as at temperatures at or below approximately 450 degrees Celsius. The use of low-temperature deposition processes for forming the oxide-semiconductor channel layers 218 reduce and/or minimize the likelihood of damage and/or degradation to the integrated circuit devices 108 and other layers and/or structures formed in the device layer 102 that might otherwise occur due to exposure to high temperatures. In this way, the use of oxide-semiconductor materials for the oxide-semiconductor channel layers 218 of the transistor structures 212 of the memory cell structures 202 enable the device layer 102 and the memory array 122 of the semiconductor device 100 to be formed monolithically (e.g., built up on the same die), as described in greater detail in connection with FIGS. 3A-3D, 4A-4O, 6A-6P, and/or 7.

As indicated above, FIG. 2 is provided as an example. Other examples may differ from what is described with regard to FIG. 2.

FIGS. 3A-3D are diagrams of an example implementation 300 of forming the semiconductor device 100 described herein. In some implementations, one or more of the semiconductor processing operations described in connection with FIGS. 3A-3D may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIG. 3A, the substrate 106 may be provided. The substrate 106 may be provided in the form of a semiconductor wafer such as a silicon (Si) wafer, an SOI wafer, and/or another type of semiconductor work piece. The semiconductor device 100 may be formed on the semiconductor wafer with other semiconductor devices.

As shown in FIG. 3B, the integrated circuit devices 108 may be formed in and/or on the substrate 106 in the device layer 102 of the semiconductor device 100. One or more semiconductor processing tools may be used to form one or more portions of the integrated circuit devices 108. For example, an ion implantation tool may be used to dope one or more regions in the substrate 106 with one or more types of dopants to form well regions, implant regions, and/or other types of doped regions in the substrate 106 for the integrated circuit devices 108. As another example, a deposition tool may be used to perform various deposition operations to deposit layers and/or structures of the integrated circuit devices 108, and/or to deposit photoresist layers for etching the substrate 106 and/or portions of the deposited layers.

As another example, an exposure tool may be used to expose the photoresist layers to form patterns in the photoresist layers. As another example, a developer tool may develop the patterns in the photoresist layers. As another example, an etch tool may be used to etch the substrate 106 and/or portions of the deposited layers to form the integrated circuit devices 108. As another example, a planarization tool may be used to planarize portions of the integrated circuit devices 108. As another example, a plating tool may be used to deposit metal structures and/or layers of the integrated circuit devices 108.

As further in FIG. 3B, a deposition tool is used to deposit the dielectric layer 110 over and/or on the substrate 106 and over and/or on the integrated circuit devices 108. A deposition tool may be used to deposit the dielectric layer 110 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the dielectric layer 110 after the dielectric layer 110 is deposited.

As further shown in FIG. 3B, the contacts 112 of the integrated circuit devices 108 may be formed through the dielectric layer 110. The contacts 112 may be formed in recesses in the dielectric layer 110. In some implementations, a pattern in a photoresist layer is used to etch the dielectric layer 110 to form the recesses. In these implementations, a deposition tool may be used to form the photoresist layer on the dielectric layer 110. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 110 based on a pattern to form the recesses.

The contacts 112 may be formed in the recesses. In some implementations, a contact 112 (e.g., a gate contact) is formed on a gate structure of an integrated circuit device 108. In some implementations, a contact 112 (e.g., a source/drain contact) is formed on a source/drain region of an integrated circuit device 108. A deposition tool may be used to deposit the material of the contacts 112 in the recesses using a CVD technique, a PVD technique, an ALD technique, an electroplating technique, and/or another suitable deposition technique. The material of the contacts 112 may be deposited in one or more deposition operations. In some implementations, a seed layer is first deposited, and the material of the contacts 112 is deposited on the seed layer. In some implementations, a planarization tool is used to perform a planarization operation (e.g., a CMP operation) to planarize the contacts 112 after the contacts 112 are deposited such that the tops of the contacts 112 are approximately co-planar with the top of the dielectric layer 110.

As shown in FIG. 3C, the interconnect layer 104 (or a portion thereof) of the semiconductor device 100 may be formed above the device layer 102. One or more deposition tools are used to deposit alternating layers of ILD layers 114 and ESLs 116 in the interconnect layer 104 of the semiconductor device 100. In this way, the ILD layers 114 and the ESLs 116 may be arranged in the z-direction in the semiconductor device 100. One or more deposition tools may be used to deposit the ILD layers 114 and the ESLs 116 using a PVD technique, an ALD technique, a CVD technique, an oxidation technique, and/or another suitable deposition technique. In some implementations, a planarization tool may be used to planarize the ILD layers 114 and/or the ESLs 116 after the ILD layers 114 and/or the ESLs 116 are deposited.

As further shown in FIG. 3C, a deposition tool, an exposure tool, a developer tool, an etch tool, a planarization tool, a plating tool, and/or another semiconductor processing tool may be used to perform various operations to form the metallization structures 118 and to form the interconnect structures 120 in the interconnect layer 104 of the semiconductor device 100. In some implementations, the interconnect layer 104 may be formed in a plurality of layers. For example, an ILD layer 114 and an ESL 116 may be formed (e.g., using one or more deposition tools and/or one or more planarization tools), recesses may be formed in and/or through the ILD layer 114 and the ESL 116 (e.g., using an exposure tool, a developer tool, and/or an etch tool), and a layer 120a (e.g., the M0 layer) of metallization structures 118 may be formed in the ILD layer 114 and the ESL 116 (e.g., using one or more deposition tools and/or one or more planarization tools). Another ILD layer 114 and another ESL 116 may be formed, and the layer 122a (e.g., the V0 layer) of interconnect structures 120 may be formed in the ILD layer 114 and the ESL 116. Additional layers may be formed in a similar manner.

One or more deposition tools may be used to deposit the metallization structures 118 and/or the interconnect structures 120 using a PVD technique, an ALD technique, a CVD technique, an electroplating technique (e.g., an electro-chemical plating technique), and/or another suitable deposition technique. In some implementations, a planarization tool may be used to planarize the metallization structures 118 and/or the interconnect structures 120.

As shown in FIG. 3D, the memory array 122 may be formed above the device layer 102 so that the device layer 102 and the memory array 122 are stacked and vertically arranged in the semiconductor device 100. In some implementations, the interconnect layer 104 is formed above the device layer 102, and the memory array 122 is formed above the device layer 102.

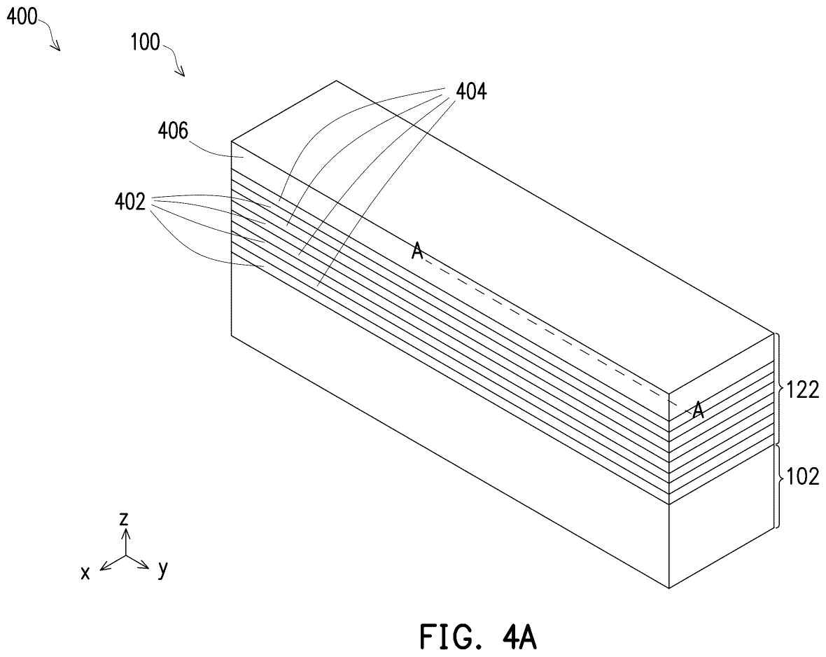

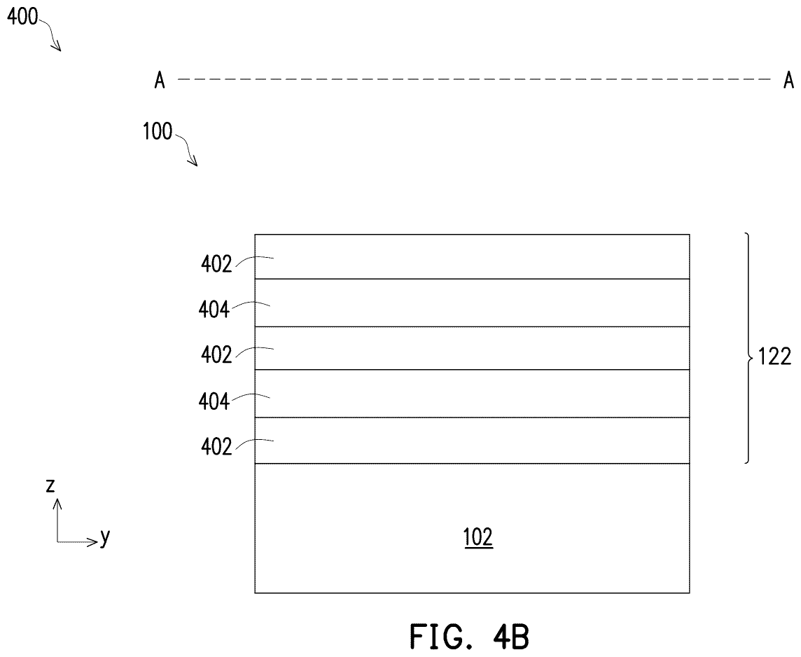

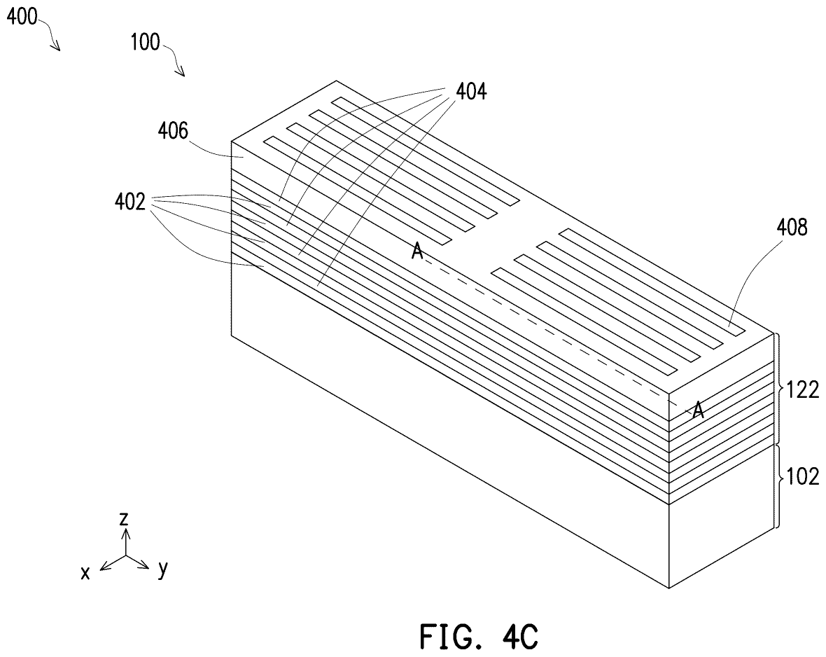

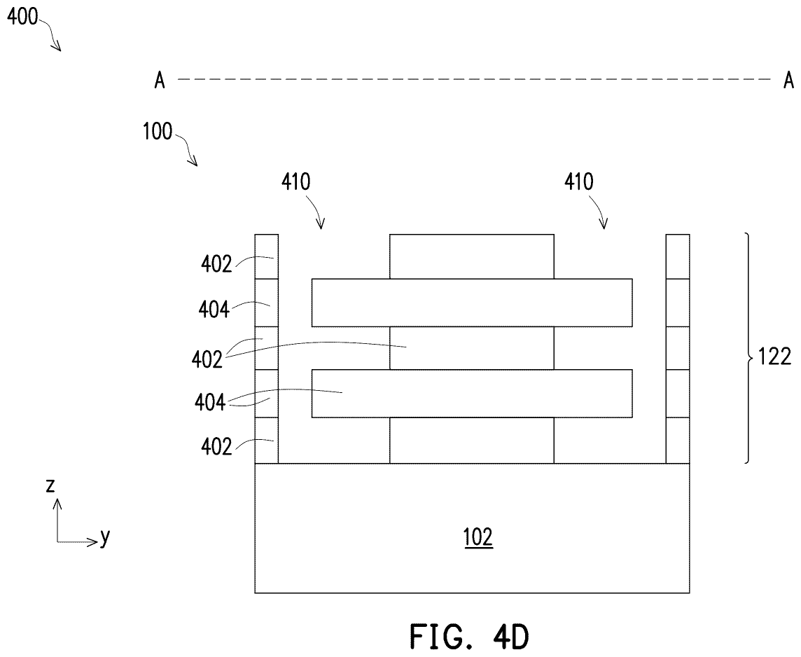

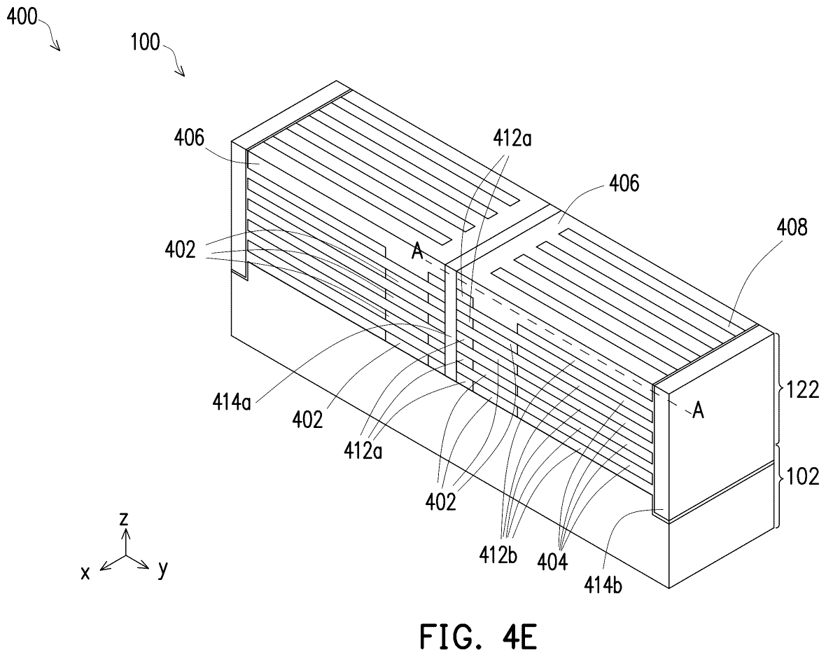

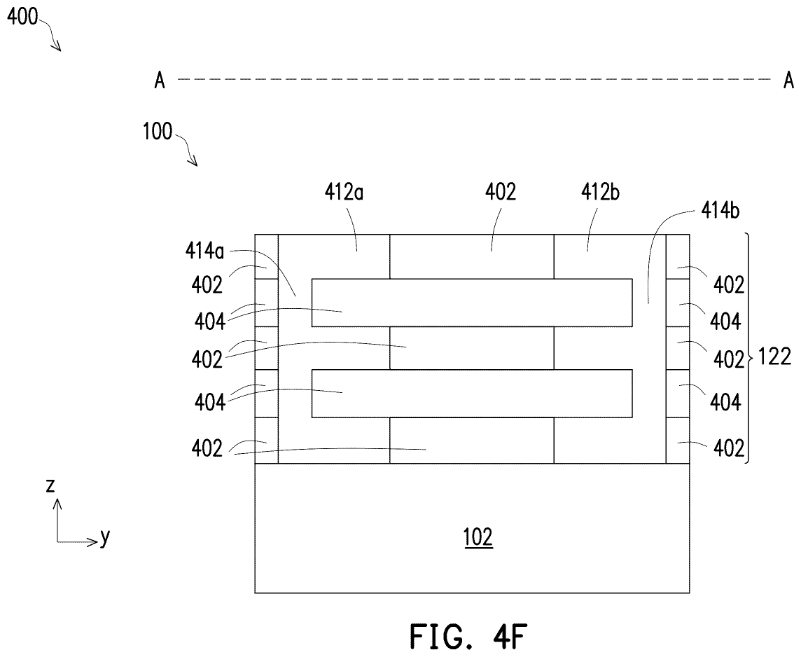

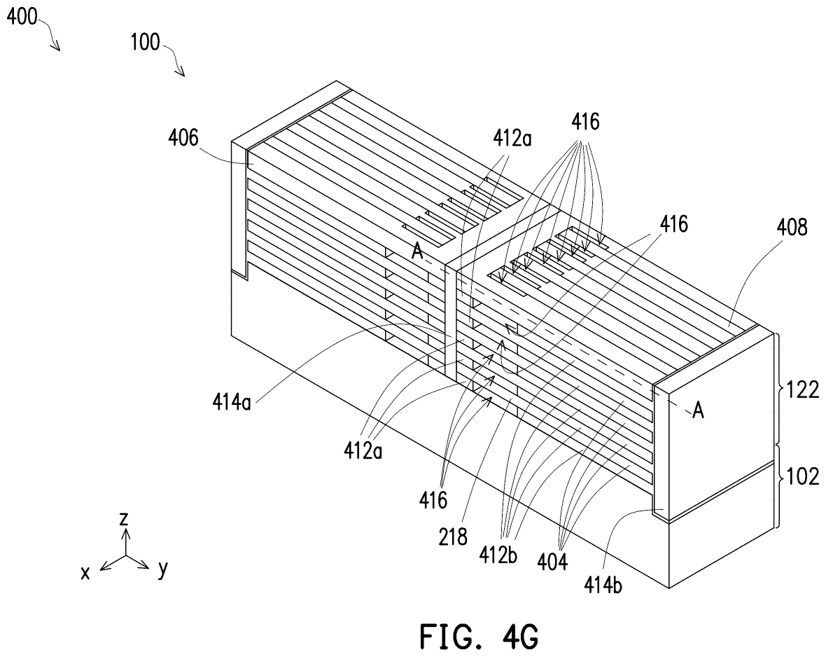

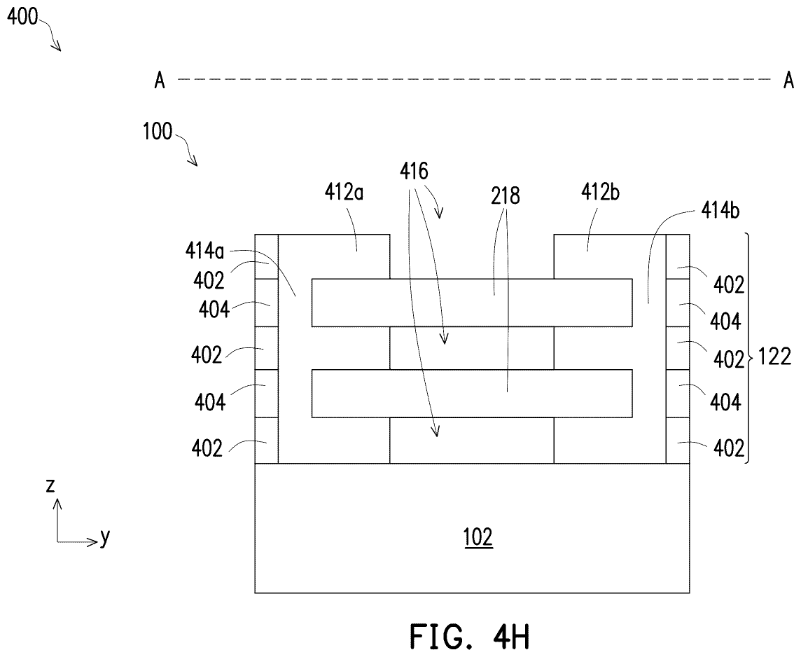

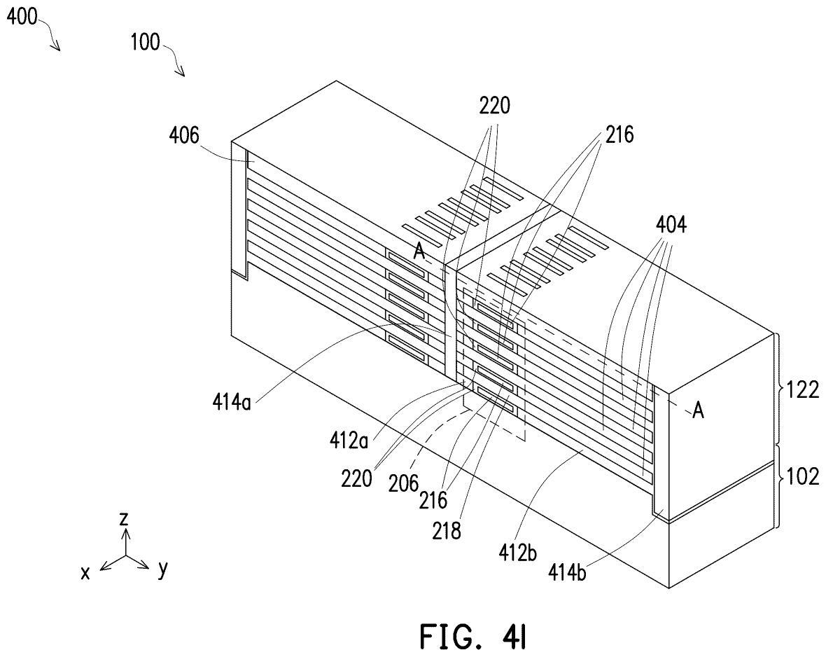

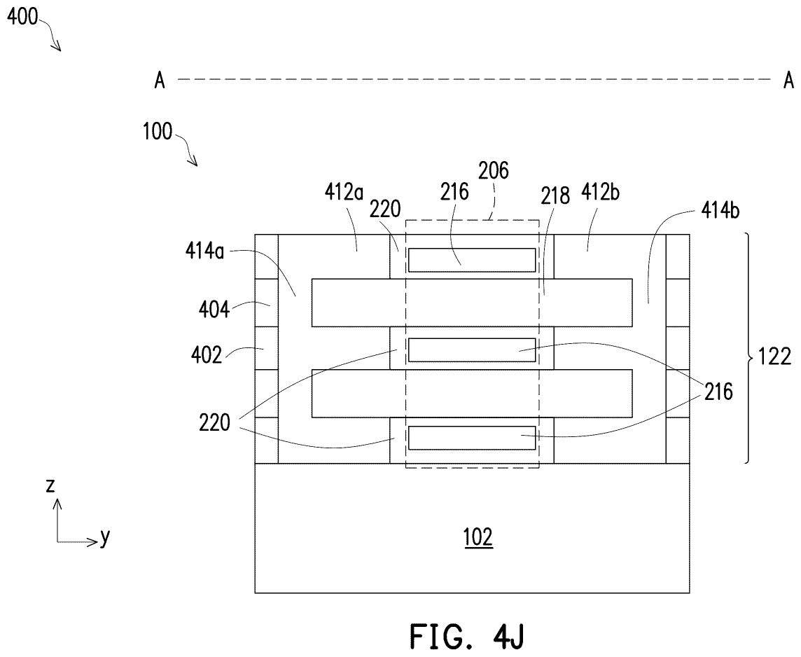

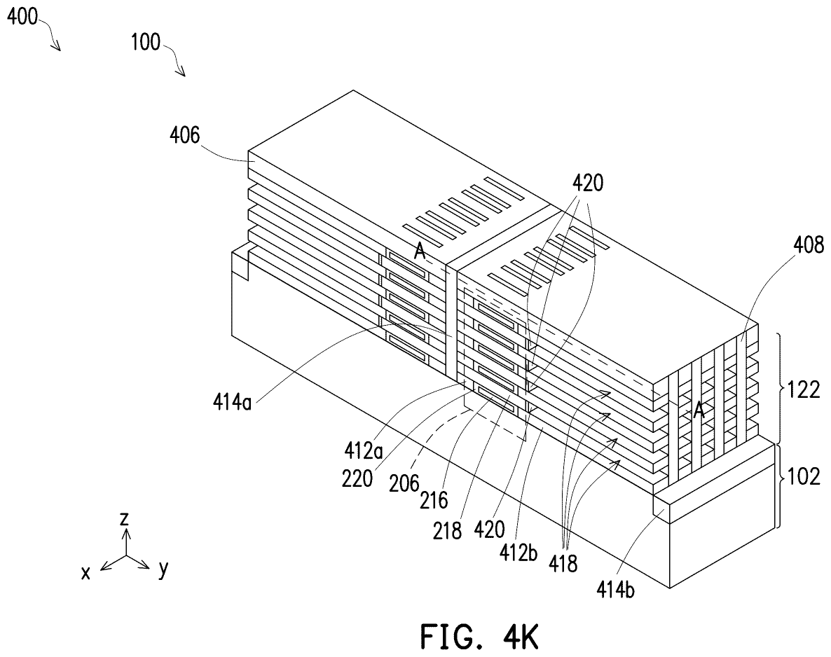

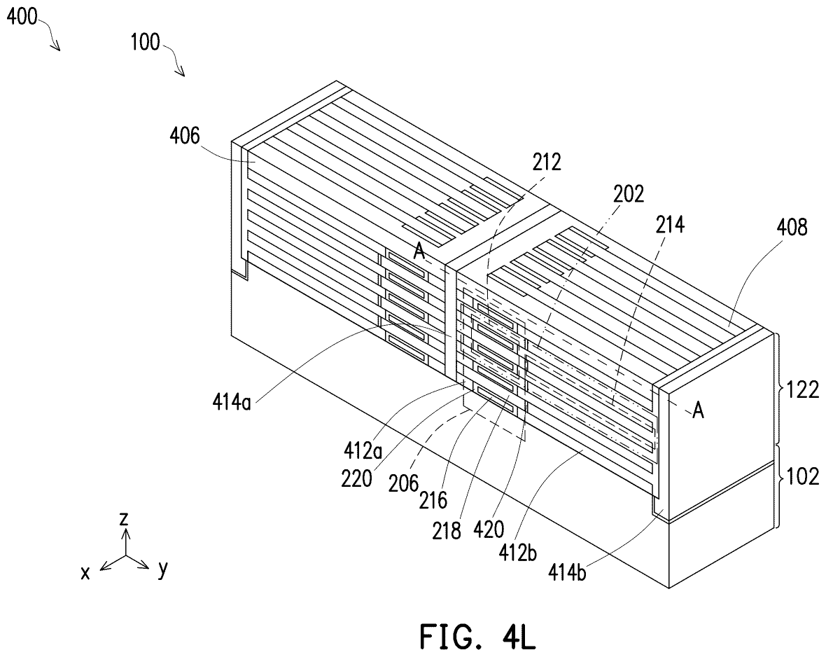

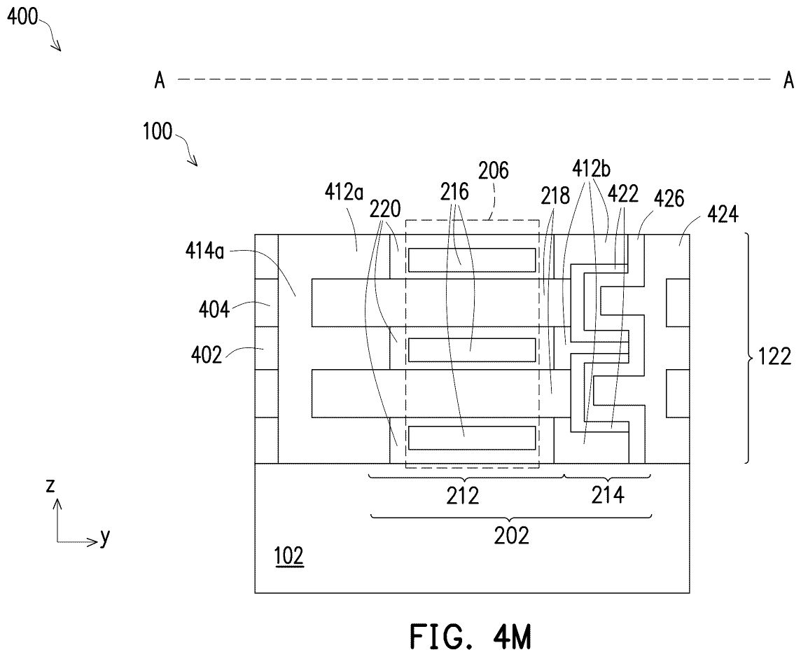

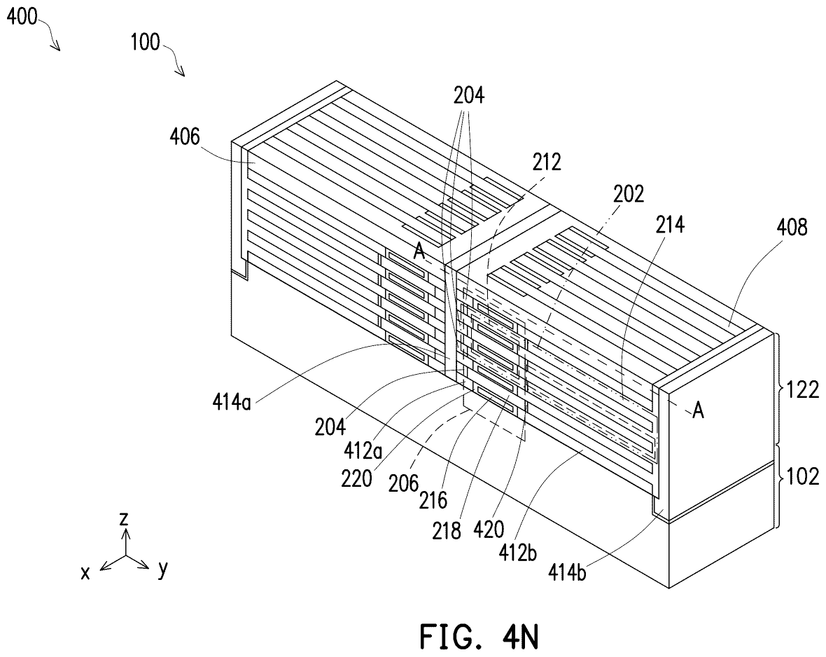

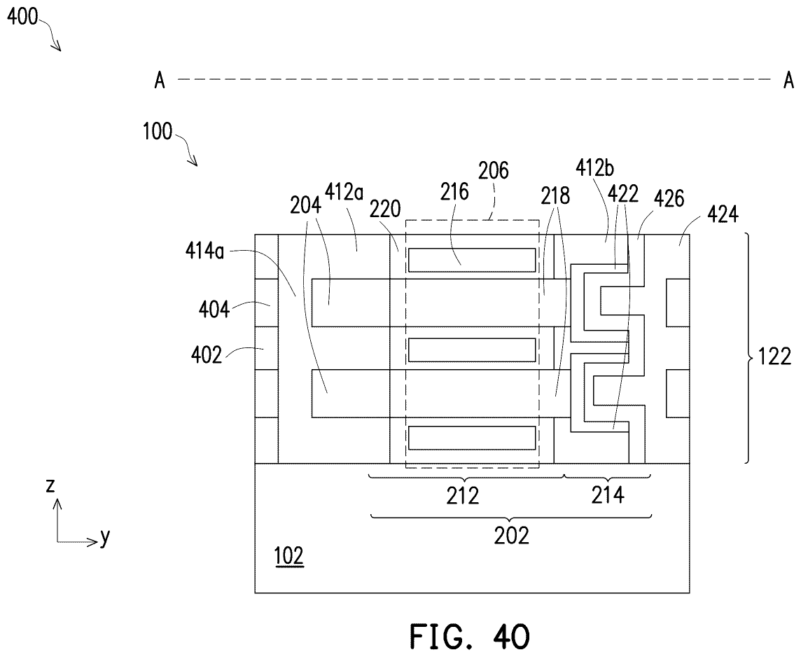

The memory array 122 may be formed above the device layer 102 (and the integrated circuit devices 108 included in the device layer 102) using semiconductor processing techniques described in connection with FIGS. 4A-4O, 6A-5Q, and/or 7, among other examples. The device layer 102 and the memory array 122 may be monolithically formed in that the device layer 102 may be formed on a semiconductor die, and the memory array 122 may be formed above the device layer 102 on the same semiconductor die, as opposed to the memory array 122 being formed on a separate semiconductor die that is then bonded to the semiconductor die on which the device layer 102 was formed.

As indicated above, FIGS. 3A-3D are provided as an example. Other examples may differ from what is described with regard to FIGS. 3A-3D.

FIGS. 4A-4O are diagrams of an example implementation 400 of forming a memory array 122 described herein. In particular, the example implementation 400 includes an example of forming the example implementation 200 of the memory array 122. In some implementations, one or more of the semiconductor processing operations described in connection with FIGS. 4A-4O may be performed using one or more semiconductor processing tools, such as a deposition tool, an exposure tool, a developer tool, an etch tool, a planarization tool, a wafer/die transport tool, and/or another type of semiconductor processing tool.

The semiconductor processing operations described in connection with FIGS. 4A-4O may be performed as part of the process for forming the semiconductor device 100 described in connection with FIGS. 3A-3D. For example, the semiconductor processing operations described in connection with FIGS. 4A-4O may be performed to form the memory array 122 above the device layer 102 of the semiconductor device 100. In this way, the device layer 102 and the

memory array 122 (and in some implementations, the interconnect layer 104) are monolithically manufactured and vertically integrated on the same semiconductor die.

As shown in a perspective view of the semiconductor device 100 in FIG. 4A and in a cross-section view in FIG. 4B along the line A-A in FIG. 4A, a layer stack may be formed above the device layer 102. The layer stack may include an alternating arrangement of metal layers 402 and oxide-semiconductor layers 404. The layer stack may be formed such that the metal layers 402 and the oxide-semiconductor layers 404 alternate in the z-direction in the semiconductor device 100. Moreover, a masking layer 406 may be formed above the layer stack.

The metal layers 402 may each include one or more metal materials or metal-containing materials, such as tungsten (W), cobalt (Co), ruthenium (Ru), titanium (Ti), aluminum (Al), copper (Cu), gold (Au), titanium nitride (TiN), and/or tantalum nitride (TaN), among other examples. In some implementations, the metal layers 402 include the same metal material (or the same metal-containing material). In some implementations, two or more of the metal layers 402 include different metal materials (or different metal-containing materials).

The oxide-semiconductor layers 404 may each include one or more oxide-semiconductor materials. In some implementations, the oxide-semiconductor layers 404 include an n-type oxide-semiconductor material such as indium gallium zinc oxide (InGaZnO or IGZO), zinc oxide (ZnO), indium oxide (InₓO_{y} such as In₂O₃), tin dioxide (SnO₂), among other examples. In some implementations, the oxide-semiconductor layers 404 include a p-type oxide-semiconductor material such as nickel oxide (NiO), copper oxide (CuₓO such as Cu₂O), copper aluminum oxide (CuAlOₓ such as CuAlO₂), copper gallium oxide (CuGaOₓ such as CuGaO₂), copper indium oxide (CuInOₓ such as CuInO₂), strontium copper oxide (SrCuₓO_{y} such as SrCu₂O₂), and/or tin oxide (SnO), among other examples. In some implementations, the oxide-semiconductor layers 404 include the same oxide-semiconductor material. In some implementations, two or more of the oxide-semiconductor layers 404 include different oxide-semiconductor materials.

The metal layers 402 and the oxide-semiconductor layers 404 may be formed using low-temperature deposition processes such as CVD. For example, a deposition tool may be used to deposit the metal layers 402 using a CVD technique, a PVD technique, an electroplating technique, and/or another suitable low-temperature deposition technique. As another example, a deposition tool may be used to deposit the oxide-semiconductor layers 404 using a CVD technique such as low-pressure CVD (LPCVD) and/or plasma-enhanced CVD (PECVD), among other examples. These deposition techniques may be performed at temperatures that are lower than the temperatures for forming semiconductor layers by epitaxy, such as at temperatures at or below approximately 450 degrees Celsius. The use of low-temperature processes for forming the metal layers 402 and the oxide-semiconductor layers 404 reduces and/or minimizes the likelihood of damage and/or degradation to the integrated circuit devices 108 and other layers and/or structures formed in the device layer 102 that might otherwise occur due to exposure to high temperatures.

In some implementations, a planarization tool may be used to perform a planarization operation (e.g., a CMP operation) to planarize the metal layers 402 and/or the oxide-semiconductor layers 404.

In some implementations, the masking layer 406 includes a metal masking layer that includes one or more metal materials or metal-containing materials, such as tungsten (W), cobalt (Co), ruthenium (Ru), titanium (Ti), aluminum (Al), copper (Cu), gold (Au), titanium nitride (TiN), and/or tantalum nitride (TaN), among other examples. In some implementations, the masking layer 406 includes a dielectric masking layer that includes one or more dielectric materials, such as a silicon oxide (SiOₓ such as SiO₂), a silicon nitride (SiₓN_{y} such as Si₃N₄), a silicon oxynitride (SiON), an aluminum oxide (AlₓO_{y} such as Al₂O₃), a silicon oxycarbide (SiOC), and/or a silicon oxycarbonitride (SiOCN), among other examples.

A deposition tool may be used to deposit the material of the masking layer 406 using a CVD technique, a PVD technique, an ALD technique, an oxidation technique, an electroplating technique, and/or another suitable deposition technique. In some implementations, a planarization tool is used to planarize the masking layer 406.

As shown in a perspective view of the semiconductor device 100 in FIG. 4C, column isolation structures 408 may be formed through the layer stack of metal layers 402 and oxide-semiconductor layers 404. The column isolation structures 408 may extend through the layer stack in the z-direction, as well as along the layer stack in the y-direction in the semiconductor device 100. The column isolation structures 408 may provide electrical isolation between adjacent columns 210 of memory cell structures 202 in the memory array 122.

The column isolation structures 408 may include one or more dielectric materials, such as a silicon oxide (SiOₓ such as SiO₂), a silicon nitride (SiₓN_{y} such as Si₃N₄), a silicon oxynitride (SiON), an aluminum oxide (AlₓO_{y} such as Al₂O₃), a silicon oxycarbide (SiOC), and/or a silicon oxycarbonitride (SiOCN), among other examples.

To form the column isolation structures 408, recesses may be formed through the metal layers 402 and the oxide-semiconductor layers 404 of the layer stack, and the material of the column isolation structures 408 may be deposited into the recesses.

In some implementations, a pattern in the masking layer 406 is used to etch the metal layers 402 and the oxide-semiconductor layers 404 to form the recesses. In these implementations, a deposition tool may be used to form a photoresist layer on the masking layer 406 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the masking layer 406 based on the pattern in the photoresist layer to transfer the pattern to the masking layer 406. In some implementations, a photoresist removal tool may be used to remove the remaining portions of the photoresist layer (e.g., using a chemical stripper, plasma ashing, and/or another technique).

An etch tool may be used to etch the metal layers 402 and the oxide-semiconductor layers 404 to form the recesses based on the pattern in the masking layer 406. In some implementations, the etch operation includes a dry etch operation (e.g., a plasma-based etch operation, a gas-based etch operation), a wet chemical etch operation, and/or another type of etch operation.

A deposition tool may be used to deposit the material of the column isolation structures 408 in the recesses using a CVD technique, a PVD technique, an ALD technique, an oxidation technique, and/or another suitable deposition technique. In some implementations, a planarization tool is used to planarize the column isolation structures 408 to remove excess material from the column isolation structures 408.

As shown a cross-section view in FIG. 4D along the line A-A in FIG. 4C, recesses 410 may be formed through the layer stack of metal layers 402 and the oxide-semiconductor layers 404. The recesses 410 may extend through the layer stack in the z-direction, as well as along the layer stack in the x-direction in the semiconductor device 100. Moreover, the recesses 410 may also extend into the ends of the metal layers 402 such that ends of the oxide-semiconductor layers 404 are exposed.

To form the recesses 410, one or more etch operations may be performed. For example, a first etch operation may be performed to form a vertical portions of recesses 410, and a second etch operation may be performed to etch the ends of the metal layers 402 exposed through the vertical portions of the recesses 410.

An etch tool may be used to perform the first etch operation using an anisotropic etch technique such as plasma-based etching. Thus, the first etch operation may primarily include vertical etching that is non-selective in that both the metal layers 402 and the oxide-semiconductor layers 404 may be etched in the first etch operation.

An etch tool may be used to perform the second etch operation using an isotropic etch technique such as wet etching or gas-based etching. A selective etchant that selectively etches the material of the metal layers 402 with minimal to no etching of the material of the oxide-semiconductor layers 404 may be used in the second etch operation. This enables the ends of the metal layers 402 to be laterally etched selectively relative to the oxide-semiconductor layers 404.

As shown in a perspective view of the semiconductor device 100 in FIG. 4E and in a cross-section view in FIG. 4F along the line A-A in FIG. 4E, the recesses 410 may be filled in with dielectric material to form row isolation structures 412a and 412b in the lateral portions of the recesses 410 and array isolation structures 414a and 414b in the vertical portions of the recesses 410. The array isolation structures 414a and 414b may provide electrical isolation between laterally adjacent portions of the memory array 122. The row isolation structures 412a and 412b may provide electrical isolation between adjacent rows 208 of memory cell structures 202 in the memory array 122. For example, the row isolation structures 412a may provide electrical isolation between vertically adjacent bit line conductive structures 204 that are to be formed for the rows 208 of the memory cell structures 202 in the memory array 122, and the row isolation structures 412b may provide electrical isolation between memory structures 214 of vertically adjacent rows 208 of memory cell structures 202 in the memory array 122.

In some implementations, the row isolation structures 412a and 412b and the array isolation structures 414a and 414b may include a liner and a dielectric core. The liner may include a silicon nitride (SiₓN_{y} such as Si₃N₄), an aluminum oxide (AlₓO_{y} such as Al₂O₃), and/or another suitable dielectric material, and the dielectric core may include a silicon oxide (SiOₓ such as SiO₂), a silicon nitride (SiₓN_{y} such as Si₃N₄), a silicon oxynitride (SiON), and/or another suitable dielectric material.

A deposition tool may be used to deposit the material of the row isolation structures 412a and 412b and the array isolation structures 414a and 414b using a PVD technique, a CVD technique, an ALD technique, and/or another suitable deposition technique. In some implementations, a planarization tool is used to planarize the array isolation structures 414a and 414b to remove excess material from the array isolation structures 414a and 414b.

As shown in a perspective view of the semiconductor device 100 in FIG. 4G and in a cross-section view in FIG. 4H along the line A-A in FIG. 4G, remaining portions of the metal layers 402 between the array isolation structures 414a and 414b may be removed, which exposes portions of the oxide-semiconductor layers 404 that were located vertically between the remaining portions of the metal layers 402. This enables the portions of the oxide-semiconductor layers 404 to be trimmed to define the oxide-semiconductor channel layers 218 of the memory cell structures 202 of the memory array 122.

To provide access to the remaining portions of the metal layers 402, gate openings 416 may be formed vertically (e.g., in the z-direction) through the layer stack of metal layers 402 and oxide-semiconductor layers 404. The remaining portions of the metal layers 402 may be etched (e.g., in the x-direction) through the gate openings 416 to extend the gate openings 416 along top and bottom surfaces of the portions of the oxide-semiconductor layers 404 that were located vertically between the remaining portions of the metal layers 402.

To form the gate openings 416, one or more etch operations may be performed. For example, a first etch operation may be performed to form vertical portions of gate openings 416, and a second etch operation may be performed to etch the remaining portions of the metal layers 402 exposed through the vertical portions of the gate openings 416.

An etch tool may be used to perform the first etch operation using an anisotropic etch technique such as plasma-based etching. Thus, the first etch operation may primarily include vertical etching that is non-selective in that both the metal layers 402 and the oxide-semiconductor layers 404 may be etched in the first etch operation.

An etch tool may be used to perform the second etch operation using an isotropic etch technique such as wet etching or gas-based etching. A selective etchant that selectively etches the material of the metal layers 402 with minimal to no etching of the material of the oxide-semiconductor layers 404 may be used in the second etch operation. This enables the metal layers 402 to be laterally etched selectively relative to the oxide-semiconductor layers 404.

As shown in a perspective view of the semiconductor device 100 in FIG. 4I and in a cross-section view in FIG. 4J along the line A-A in FIG. 4I, a gate dielectric layer 220 may be formed around the oxide-semiconductor channel layers 218 exposed in the gate openings 416, and the remaining area in the gate openings 416 may be filled in with material of the word line conductive structures 206 of the memory array 122. As indicated above, the gate openings 416 include vertical portions that extend vertically (e.g., in the z-direction) along columns 210 of memory cell structures 202 in the memory array 122. Thus, the word line conductive structures 206 formed in the gate openings 416 extend vertically (e.g., in the z-direction) along columns 210 of memory cell structures 202 in the memory array 122. Portions of the word line conductive structures 206 wrapping around two or more sides of the oxide-semiconductor channel layers 218 correspond to the gate structures 216 of the memory cell structures 202 of the memory array 122.

A deposition tool may be used to perform a conformal deposition operation such as CVD and/or ALD to conformally deposit the gate dielectric layer 220. A deposition tool may be used to deposit the material of the word line conductive structures 206 (and thus, the material of the gate structures 216) using a PVD technique, a CVD technique, an ALD technique, an electroplating technique, and/or another suitable deposition technique.

As shown in a perspective view of the semiconductor device 100 in FIG. 4K, portions of the oxide-semiconductor layers 404 laterally between the oxide-semiconductor channel layers 218 and the array isolation structure 414b may be removed to form memory structure openings 418 laterally adjacent to the oxide-semiconductor channel layers 218 in the y-direction. A portion of the array isolation structure 414b may be removed to expose ends of the oxide-semiconductor layers 404. The exposed ends of the oxide-semiconductor layers 404 may be laterally etched to remove the portions of the oxide-semiconductor layers 404 laterally adjacent to the oxide-semiconductor channel layers 218. The column isolation structures 408 and the row isolation structures 412b define the memory structure openings 418.

In some implementations, an etch tool may be used to perform an anisotropic etch to remove the portion of the array isolation structure 414b. For example, the portion of the array isolation structure 414b may be removed by plasma-based etching, gas-based etching, and/or another type of anisotropic etching. In some implementations, an etch tool may be used to perform an isotropic etch to remove the portions of the oxide-semiconductor layers 404. For example, the portions of the oxide-semiconductor layers 404 may be removed by wet etching, gas-based etching, and/or another type of isotropic etching.

As further shown in FIG. 4K, metal silicide layers 420 may be formed on ends of the oxide-semiconductor channel layers 218 exposed in the memory structure openings 418. The metal silicide layers 420 may include a metal silicide material such as titanium silicide (TiSi), ruthenium silicide (RuSi), cobalt silicide (CoSi), and/or another metal silicide material. The metal silicide layers 420 may be included to achieve a low contact resistance between the oxide-semiconductor channel layers 218 and the memory structures 214 that are to be formed in the memory structure openings 418.

The metal silicide layers 420 may be formed by performing a salicidation process. The salicidation process may include using a deposition tool to deposit metal material (e.g., titanium (Ti), ruthenium (Ru), cobalt (Co)) on the exposed ends of the oxide-semiconductor channel layers 218, and performing a thermal operation (e.g., an annealing operation) to cause the metal material to react with the material of the oxide-semiconductor channel layers 218 to form the metal silicide layers 420. Unreacted metal material may be subsequently removed from the exposed ends of the oxide-semiconductor channel layers 218.

As shown in a perspective view of the semiconductor device 100 in FIG. 4L and in a cross-section view in FIG. 4M along the line A-A in FIG. 4L, the memory structures 214 of the memory cell structures 202 of the memory array 122 may be formed. The memory structures 214 may be formed in the memory structure openings 418 so that the memory structures 214 are electrically coupled and/or physically coupled to the oxide-semiconductor channel layers 218 of the transistor structures 212 of the memory cell structures 202. Thus, and as shown in FIG. 4L, the memory structures 214 may be elongated in the y-direction in the semiconductor device. Moreover, and as shown in FIG. 4L, the memory structures 214 may be arranged in a grid in the x-direction (e.g., in rows 208) and in the y-direction (e.g., in columns 210).

As shown in in FIG. 4M, a memory structure 214 may include a capacitor structure that includes electrode layers 422 and 424 that are spaced apart by an insulator layer 426. The electrode layer 422 may be electrically coupled and/or physically coupled to an oxide-semiconductor channel layer 218 of a transistor structure 212. The electrode layers 422 and 424 may each include one or more electrically conductive metals, one or more electrically conductive metal-containing materials, one or more electrically conductive ceramic materials, and/or other types of electrically conductive materials. Examples include tungsten (W), cobalt (Co), ruthenium (Ru), titanium (Ti), aluminum (Al), copper (Cu), gold (Au), titanium nitride (TiN), and/or tantalum nitride (TaN), among other examples. The insulator layer 426 may include one or more electrically insulating materials. In some implementations, the insulator layer 426 includes one or more low-k dielectric materials such as silicon oxide (SiOₓ such as SiO₂). Additionally and/or alternatively, the insulator layer 426 may include one or more high-k dielectric materials such as zirconium oxide (ZrOₓ such as ZrO₂), aluminum oxide (AlₓO_{y} such as Al₂O₃), silicon nitride (SiₓN_{y} such as Si₃N₄), yttrium oxide (YₓO_{y} such as Y₂O₃), lanthanum oxide (LaₓO_{y} such as La₂O₃), and/or hafnium oxide (HfOₓ such as HfO₂), among other examples. In some implementations, the insulator layer 426 is a multiple-layer stack that includes a plurality of dielectric layers. For example, the insulator layer 426 may include a ZrO₂/Al₂O₃/ZrO₂ (ZAZ) layer stack.

Alternatively, a memory structure 214 may include another type of memory structure, such as a magnetic tunnel junction (MTJ), a resistive memory structure, a phase change memory structure, and/or another type of memory structure.

As shown in FIGS. 4N and 4O, portions of the oxide-semiconductor channel layers 218 laterally between the gate structures 216 and the array isolation structure 414a (e.g., portions of the oxide-semiconductor channel layers 218 vertically between the row isolation structures 412a) may be removed and replaced with the bit line conductive structures 204. The bit line conductive structures 204 may be formed between vertically adjacent row isolation structures 412a so that the bit line conductive structures 204 are elongated in, and extend in, the x-direction.

The bit line conductive structures 204 are formed such that the bit line conductive structures 204 are electrically coupled and/or physically coupled to the oxide-semiconductor channel layers 218 of one or more transistor structures 212 of one or more memory cell structures 202. In some implementations, bit line conductive structures 204 extend laterally across a row 208 of two or more memory cell structures 202 in the x-direction so that the oxide-semiconductor channel layers 218 of the transistor structures 212 of the memory cell structures 202 are electrically coupled together.

An etch tool may be used to etch the portions of the oxide-semiconductor channel layers 218 laterally between the gate structures 216 and the array isolation structure 414a. In some implementations, the etch operation includes a wet chemical etch operation in which a wet

etchant is used to laterally etch the portions of the oxide-semiconductor channel layers 218. In some implementations, another type of etch operation, such as a dry etch operation, is performed to etch the portions of the oxide-semiconductor channel layers 218.

Removal of the portions of the oxide-semiconductor channel layers 218 leaves behind bit line conductive structure openings laterally between the gate structures 216 and the array isolation trench 414a. These openings may be filled in with electrically conductive material (e.g., metal material) of the bit line conductive structures 204. A deposition tool may be used to deposit the material of the bit line conductive structures 204 using a CVD technique, a PVD technique, an ALD technique, an electroplating technique, and/or another suitable deposition technique. The material of the bit line conductive structures 204 may be deposited in one or more deposition operations.

As indicated above, FIGS. 4A-4O are provided as an example. Other examples may differ from what is described with regard to FIGS. 4A-4O.

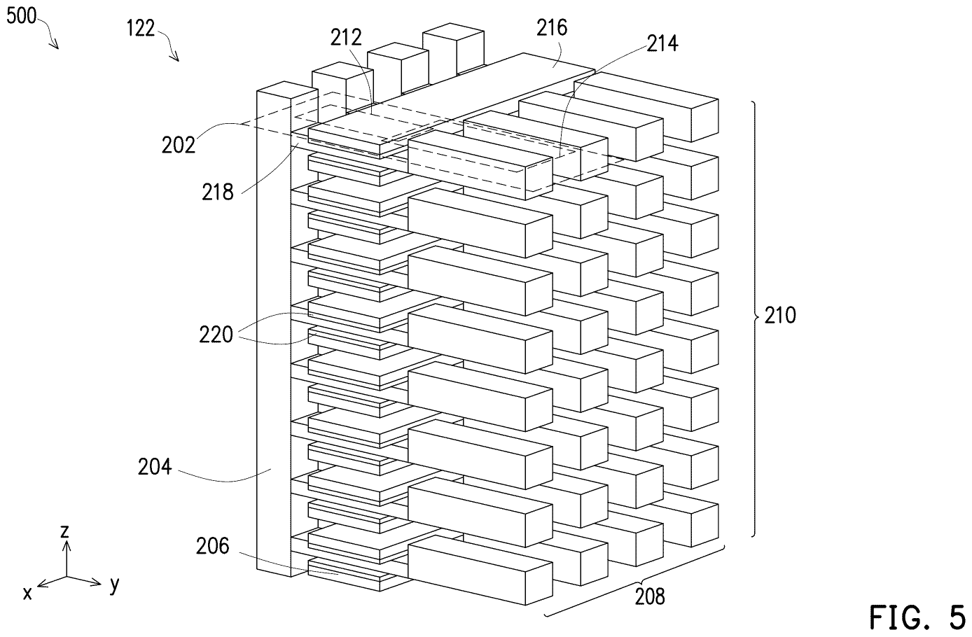

FIG. 5 is a diagram of an example implementation 500 of a memory array 122 described herein. The example implementation 500 of the memory array 122 illustrated in FIG. 5 may be included above the device layer 102 and the interconnect layer 104 of the semiconductor device 100. Thus, the device layer 102, the interconnect layer 104, and the memory array 122 may be stacked and vertically arranged (e.g., in the z-direction) in the semiconductor device 100.

As shown in FIG. 5, the example implementation 500 of the memory array 122 includes a similar combination and arrangement of layers and structures as the example implementation 200 of a memory array 122 illustrated in FIG. 2. However, the example implementation 500 of the memory array 122 is a vertical bit line memory array in which the bit line conductive structures 204 of the memory array 122 vertically extend in the z-direction in the memory array 122 (and in the semiconductor device 100) as opposed to laterally extending in the memory array 122 as in the example implementation 200 of a memory array 122 illustrated in FIG. 2. In the example implementation 500 of the memory array 122, the bit line conductive structures 204 may be laterally arranged in the x-direction.

Moreover, the word line conductive structures 206 of the memory array 122 laterally extend in the x-direction in the memory array 122 (and in the semiconductor device 100) in the example implementation 500 of the memory array 122 as opposed to vertically extending in the memory array 122 as in the example implementation 200 of a memory array 122 illustrated in FIG. 2. In the example implementation 500 of the memory array 122, the word line conductive structures 206 may be vertically arranged in the z-direction.

Because of the arrangement of the bit line conductive structures 204 in the example implementation 500 of the memory array 122, a bit line conductive structure may extend across a column 210 of a plurality memory cell structures 202 in the z-direction. Because of the arrangement of the word line conductive structures 206 in the example implementation 500 of the memory array 122, a bit line conductive structure may extend across a column 210 of a plurality memory cell structures 202 in the z-direction.

As indicated above, FIG. 5 is provided as an example. Other examples may differ from what is described with regard to FIG. 5.

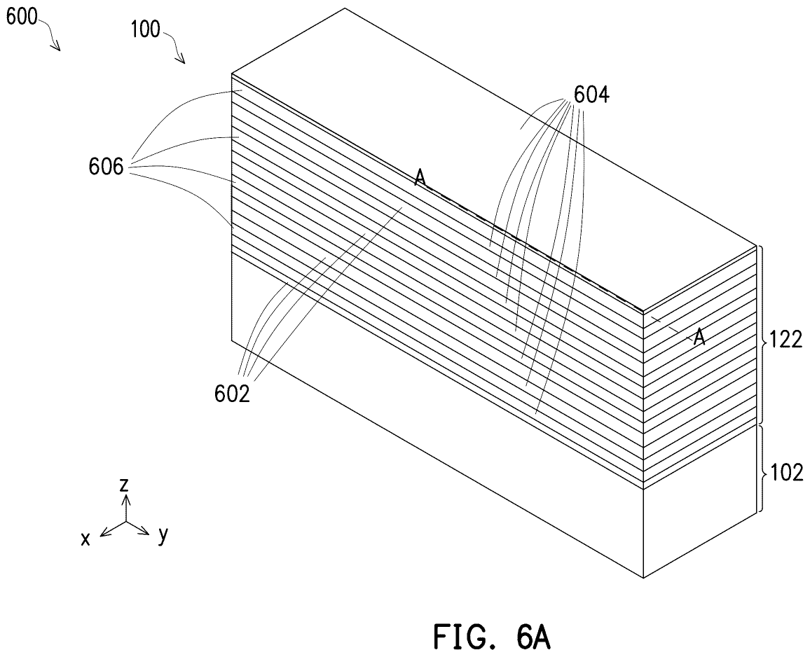

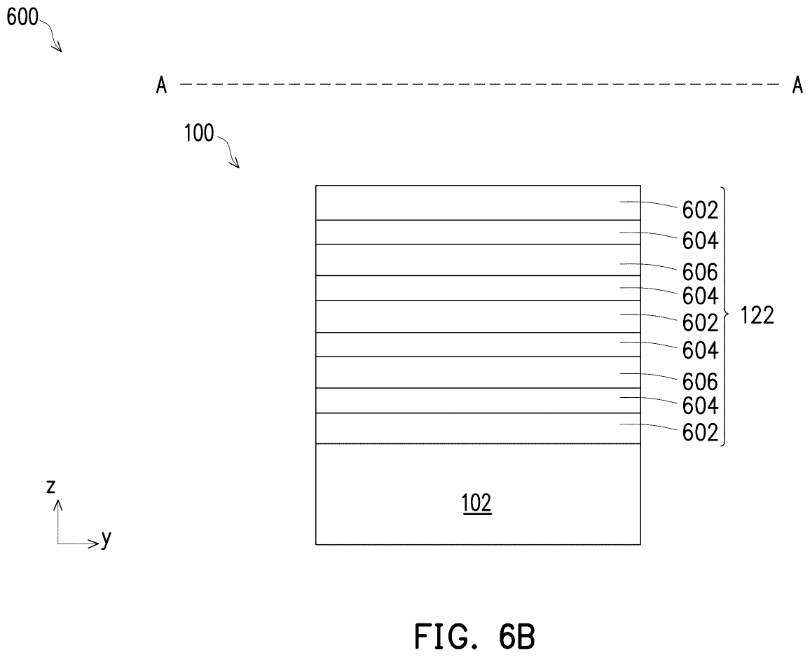

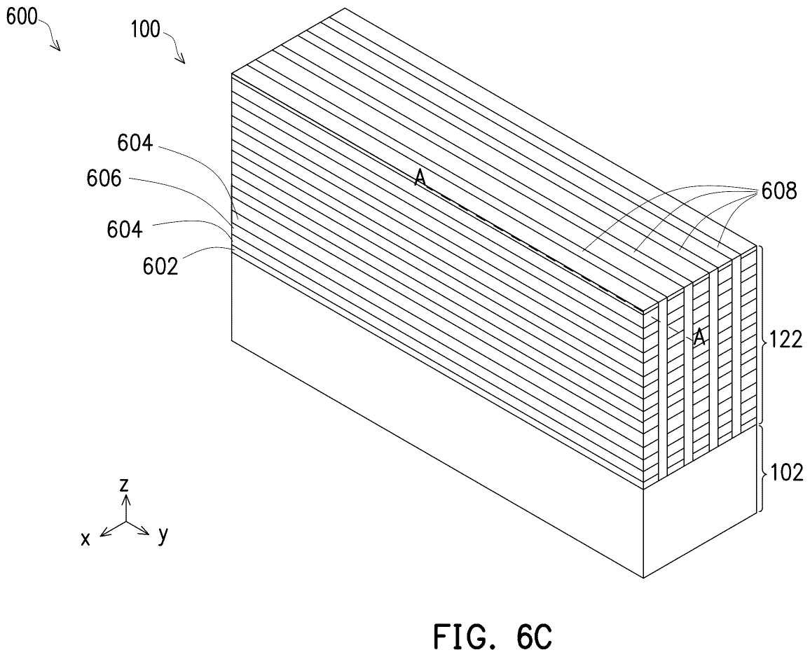

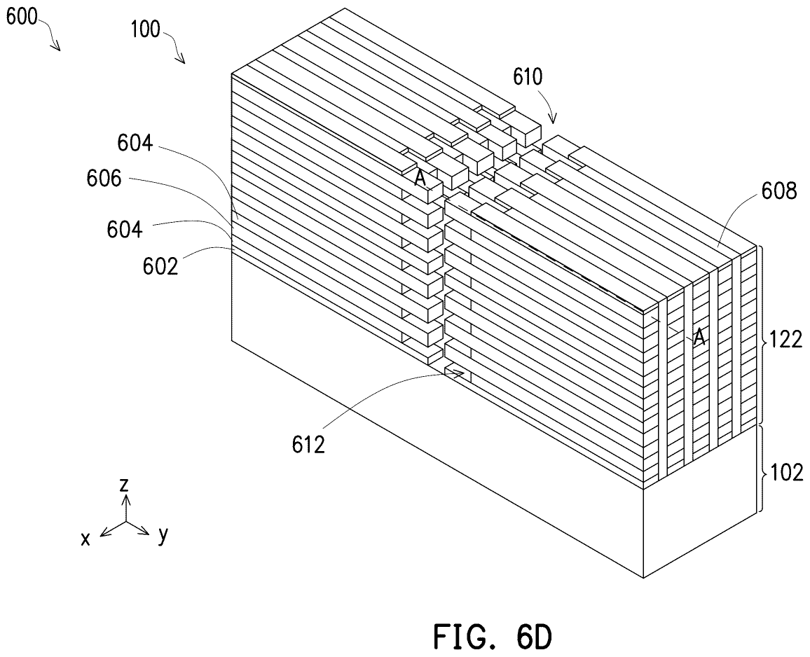

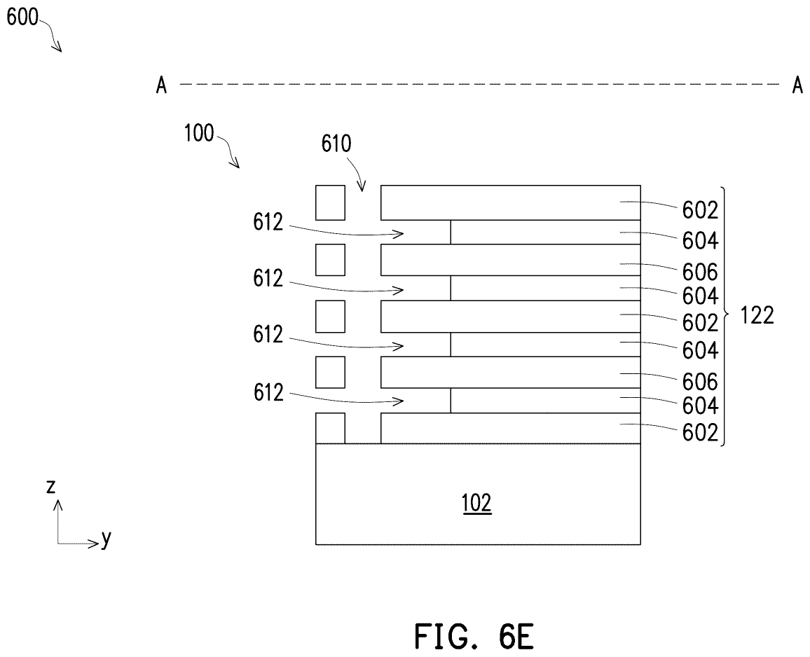

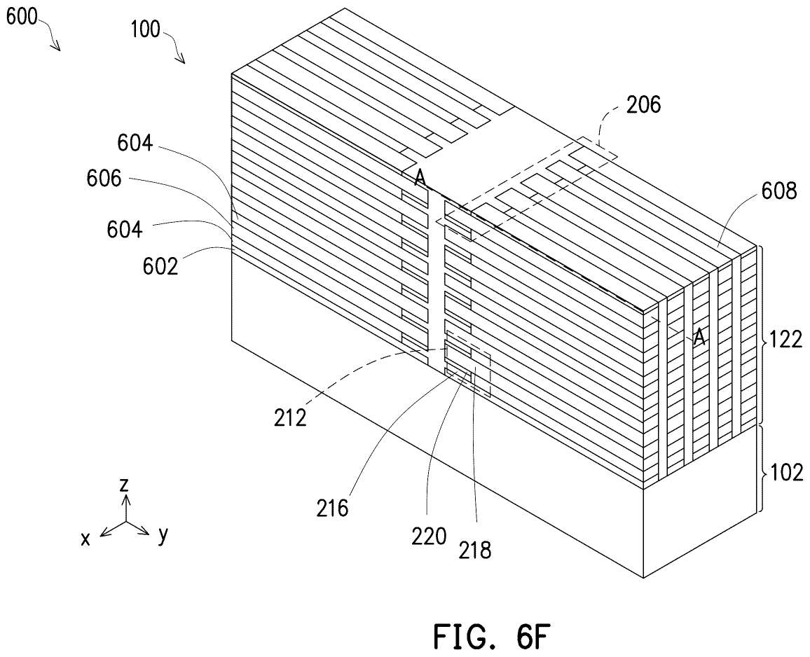

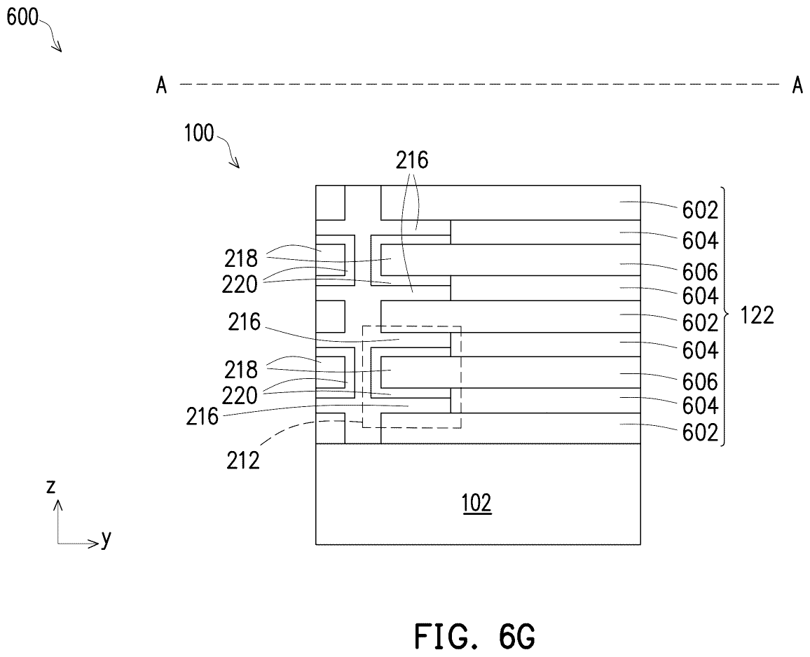

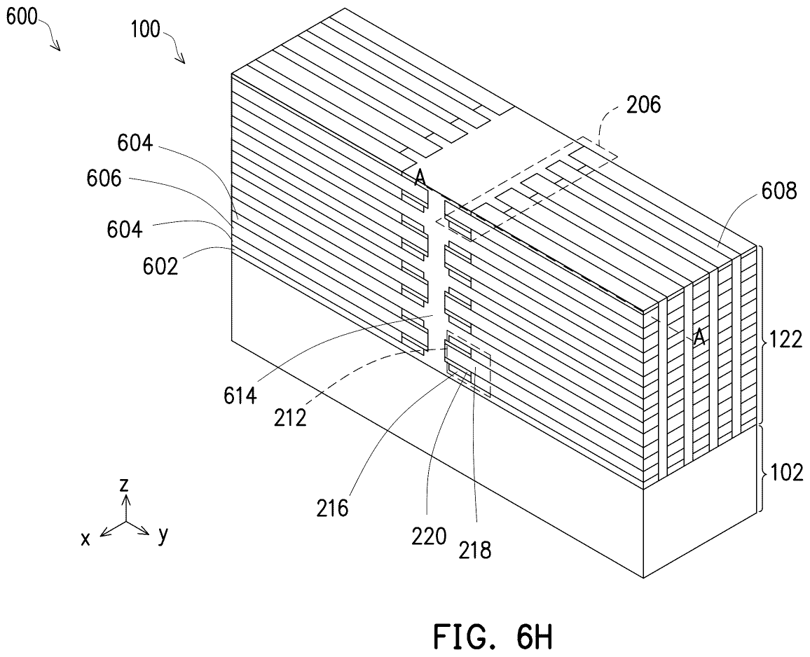

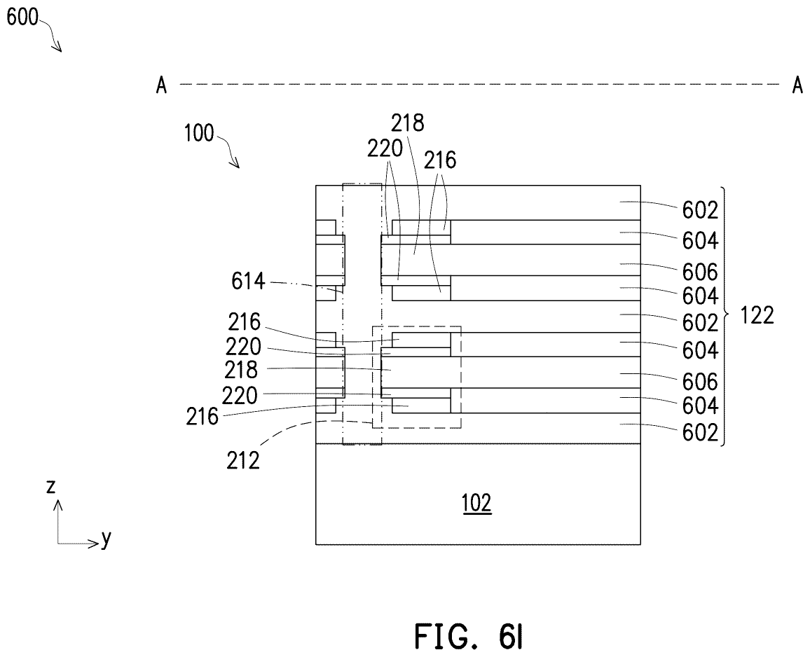

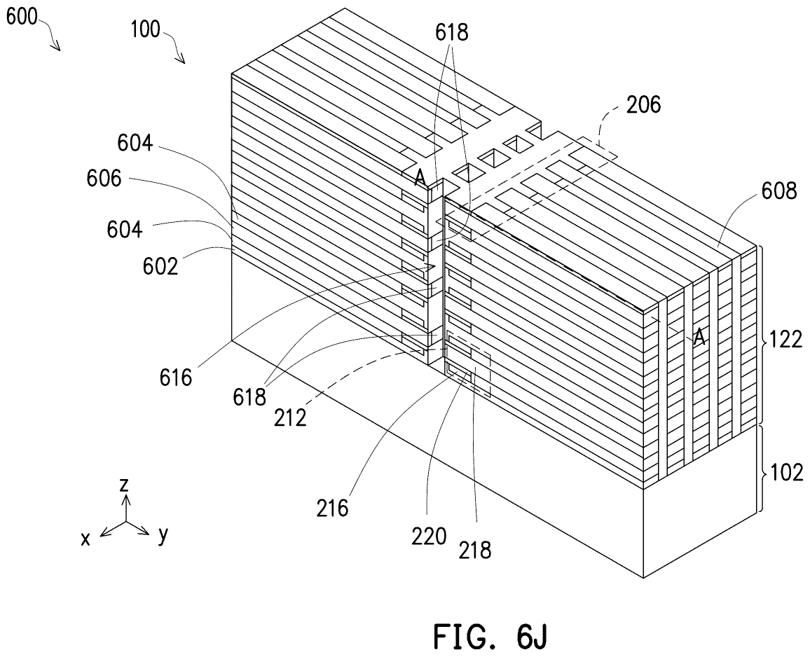

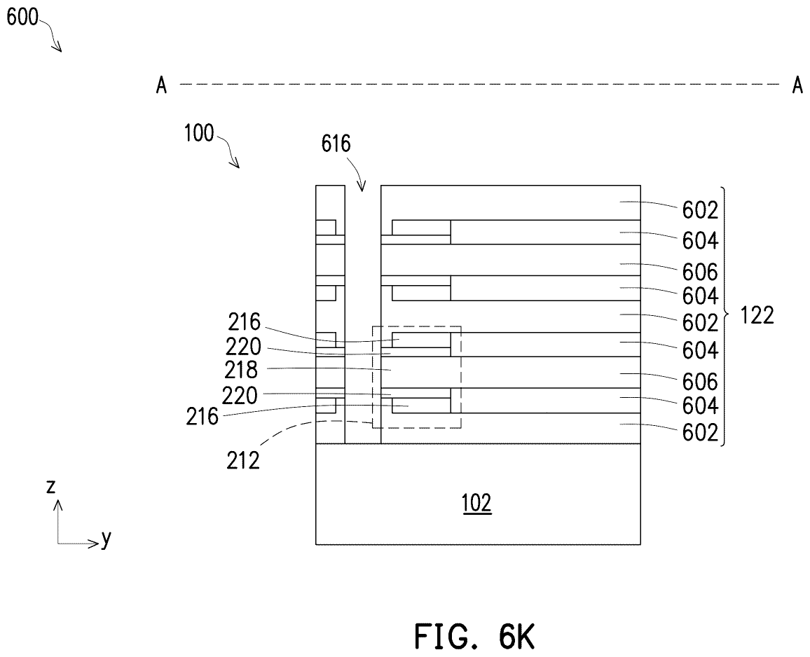

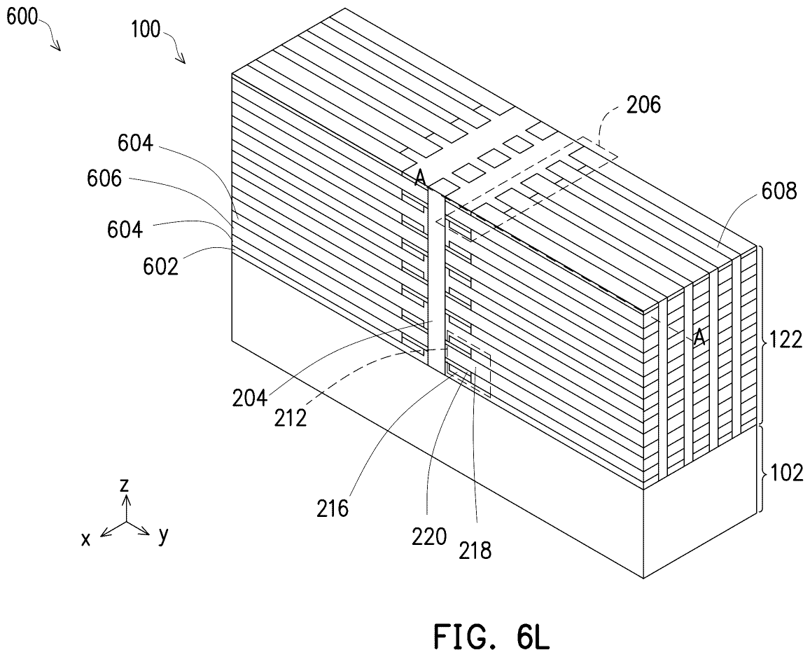

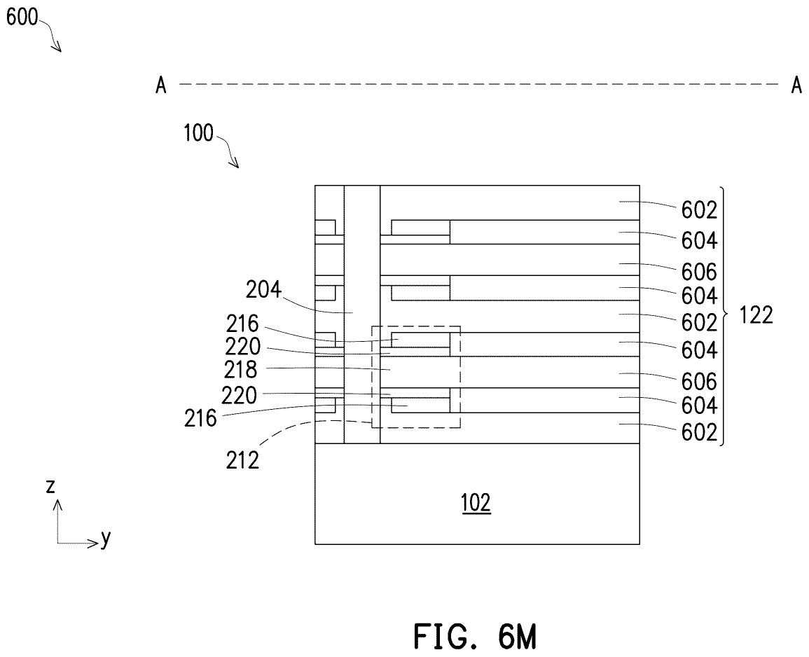

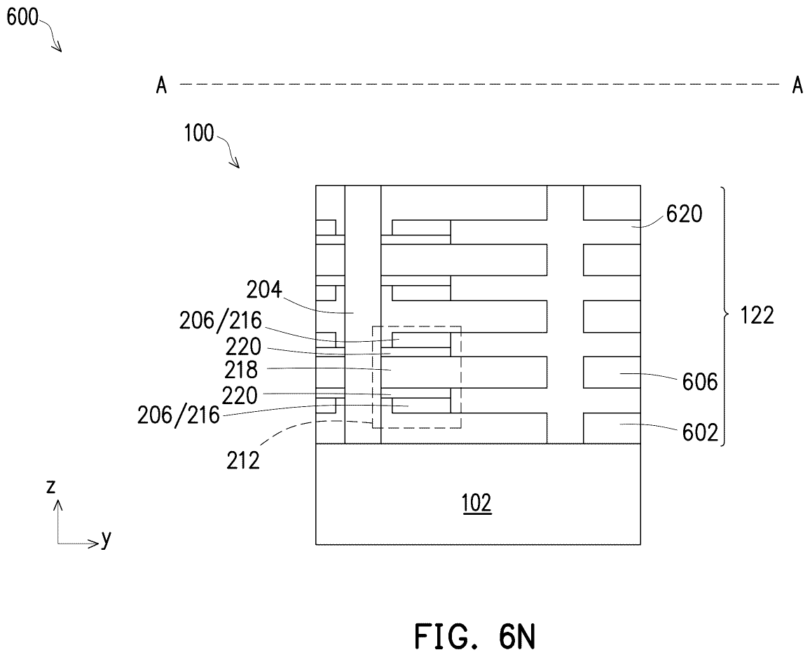

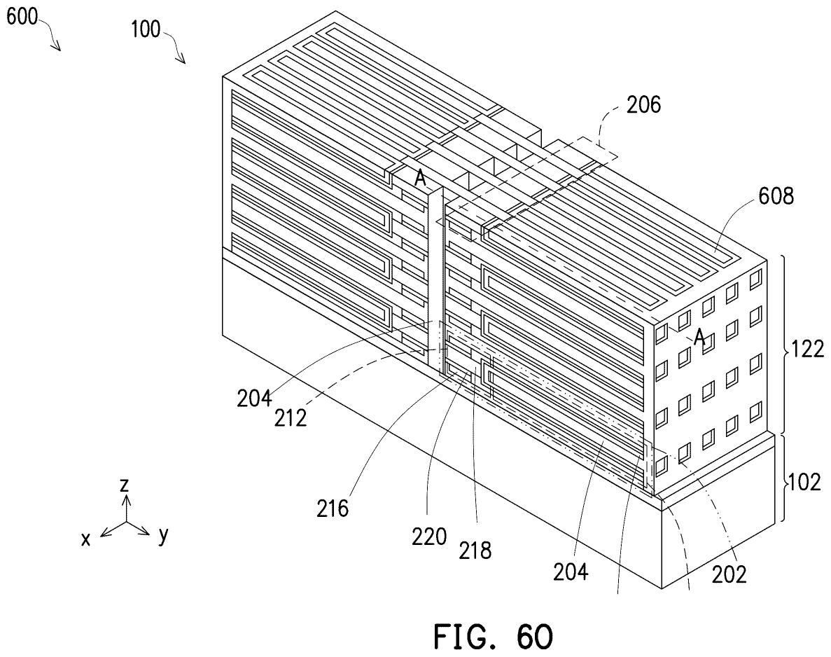

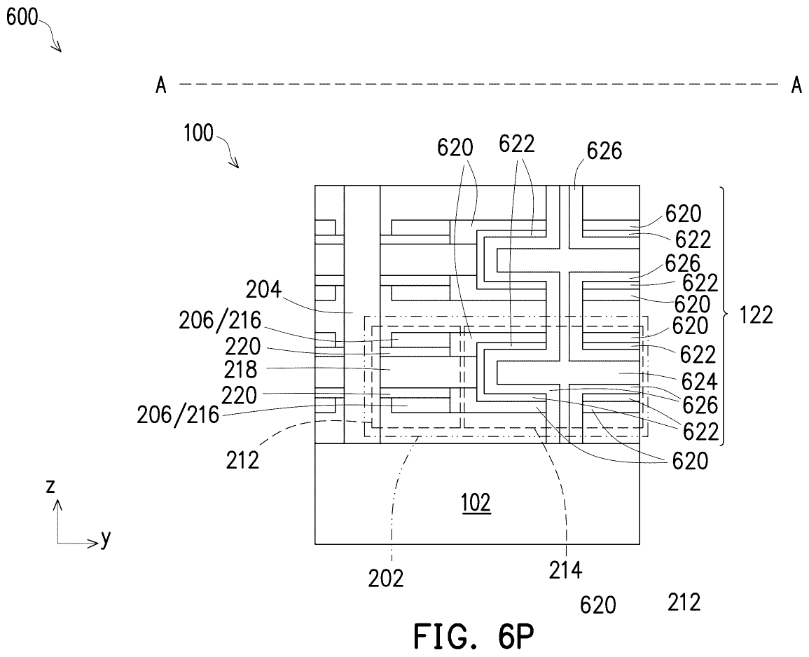

FIGS. 6A-6P are diagrams of an example implementation 600 of forming a memory array 122 described herein. In particular, the example implementation 600 includes an example of forming the example implementation 500 of the memory array 122. In some implementations, one or more of the semiconductor processing operations described in connection with FIGS. 6A-6P may be performed using one or more semiconductor processing tools, such as a deposition tool, an exposure tool, a developer tool, an etch tool, a planarization tool, a wafer/die transport tool, and/or another type of semiconductor processing tool.

The semiconductor processing operations described in connection with FIGS. 6A-6P may be performed as part of the process for forming the semiconductor device 100 described in connection with FIGS. 3A-3D. For example, the semiconductor processing operations described in connection with FIGS. 6A-6P may be performed to form the memory array 122 above the device layer 102 of the semiconductor device 100. In this way, the device layer 102 and the memory array 122 (and in some implementations, the interconnect layer 104) are monolithically manufactured and vertically integrated on the same semiconductor die.

As shown in a perspective view of the semiconductor device 100 in FIG. 6A and in a cross-section view in FIG. 6B along the line A-A in FIG. 6A, a layer stack may be formed above the device layer 102. The layer stack may include an arrangement of isolation layers 602, metal layers 604, and oxide-semiconductor layers 606. The arrangement of layers in the layer stack may include a repeating arrangement of an isolation layer 602, a metal layer 604 over and/or on the isolation layer 602, an oxide-semiconductor layer 606 over and/or on the metal layer 604, and another metal layer 604 over and/or on the oxide-semiconductor layer 606. This layer arrangement may repeat in the z-direction in the semiconductor device 100.

The isolation layers 602 may each include one or more electrically-insulating materials, such as silicon oxide (SiOₓ) or undoped silicate glass (USG). Additionally and/or alternatively, the isolation layers 602 may each include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an isolation layer 602 includes an extreme low dielectric constant (ELK) dielectric material having a dielectric constant that is less than approximately 2.5.

The metal layers 604 may each include one or more metal materials or metal-containing materials, such as tungsten (W), cobalt (Co), ruthenium (Ru), titanium (Ti), aluminum (Al), copper (Cu), gold (Au), titanium nitride (TiN), and/or tantalum nitride (TaN), among other examples. In some implementations, the metal layers 604 include the same metal material (or the same metal-containing material). In some implementations, two or more of the metal layers 402 include different metal materials (or different metal-containing materials).

The oxide-semiconductor layers 606 may each include one or more oxide-semiconductor materials. In some implementations, the oxide-semiconductor layers 404 include an n-type oxide-semiconductor material such as indium gallium zinc oxide (InGaZnO or IGZO), zinc oxide (ZnO), indium oxide (InₓO_{y} such as In₂O₃), tin dioxide (SnO₂), among other examples. In some implementations, the oxide-semiconductor layers 404 include a p-type oxide-semiconductor material such as nickel oxide (NiO), copper oxide (CuₓO such as Cu₂O), copper aluminum oxide (CuAlOₓ such as CuAlO₂), copper gallium oxide (CuGaOₓ such as CuGaO₂), copper indium oxide (CuInOₓ such as CuInO₂), strontium copper oxide (SrCuₓO_{y} such as SrCu₂O₂), and/or tin oxide (SnO), among other examples. In some implementations, the oxide-semiconductor layers 606 include the same oxide-semiconductor material. In some implementations, two or more of the oxide-semiconductor layers 404 include different oxide-semiconductor materials.

The isolation layers 602, the metal layers 604, and the oxide-semiconductor layers 606 may be formed using low-temperature deposition processes such as CVD. For example, a deposition tool may be used to deposit the isolation layers 602 using a CVD technique such as LPCVD and/or PECVD, among other examples. As another example, a deposition tool may be used to deposit the metal layers 604 using a CVD technique, a PVD technique, an electroplating technique, and/or another suitable low-temperature deposition technique. As another example, a deposition tool may be used to deposit the oxide-semiconductor layers 606 using a CVD technique such as LPCVD and/or PECVD, among other examples. These deposition techniques may be performed at temperatures that are lower than the temperatures for forming semiconductor layers by epitaxy, such as at temperatures at or below approximately 450 degrees Celsius. The use of low-temperature processes for forming the isolation layers 602, the metal layers 604, and the oxide-semiconductor layers 606 reduces and/or minimizes the likelihood of damage and/or degradation to the integrated circuit devices 108 and other layers and/or structures formed in the device layer 102 that might otherwise occur due to exposure to high temperatures.

In some implementations, a planarization tool may be used to perform a planarization operation (e.g., a CMP operation) to planarize the isolation layers 602, the metal layers 604, and/or the oxide-semiconductor layers 606.

As shown in a perspective view of the semiconductor device 100 in FIG. 6C, column isolation structures 608 may be formed through the layer stack of isolation layers 602, metal layers 604, and oxide-semiconductor layers 606. The column isolation structures 608 may extend through the layer stack in the z-direction, as well as along the layer stack in the y-direction in the semiconductor device 100.

The column isolation structures 608 may provide electrical isolation between adjacent columns 210 of memory cell structures 202 in the memory array 122. The isolation layers 602 may provide electrical isolation between adjacent rows 208 of memory cell structures 202 in the memory array 122. For example, the isolation layers 602 may provide electrical isolation between vertically adjacent word line conductive structures 206 and memory structures 214 that are to be formed for the rows 208 of the memory cell structures 202 in the memory array 122, and the column isolation structures 608 may provide electrical isolation between bit line conductive structures 204 and the memory structures 214 of laterally adjacent columns 210 of memory cell structures 202 in the memory array 122.

The column isolation structures 608 may include one or more dielectric materials, such as a silicon oxide (SiOₓ such as SiO₂), a silicon nitride (SiₓN_{y} such as Si₃N₄), a silicon oxynitride (SiON), an aluminum oxide (AlₓO_{y} such as Al₂O₃), a silicon oxycarbide (SiOC), and/or a silicon oxycarbonitride (SiOCN), among other examples.

To form the column isolation structures 608, recesses may be formed through the isolation layers 602, the metal layers 604, and the oxide-semiconductor layers 606 of the layer stack, and the material of the column isolation structures 608 may be deposited into the recesses.

In some implementations, a deposition tool may be used to form a photoresist layer on the layer stack (or on a masking layer on the layer stack) using a spin-coating technique and/or another suitable deposition technique. An exposure tool may be used to expose the photoresist layer to a radiation source to pattern the photoresist layer. A developer tool may be used to develop and remove portions of the photoresist layer to expose the pattern. An etch tool may be used to etch the isolation layers 602, the metal layers 604, and the oxide-semiconductor layers 606 to form the recesses based on the pattern. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique).

A deposition tool may be used to deposit the material of the column isolation structures 608 in the recesses using a CVD technique, a PVD technique, an ALD technique, an oxidation technique, and/or another suitable deposition technique. In some implementations, a planarization tool is used to planarize the column isolation structures 608 to remove excess material from the column isolation structures 608.

As shown in a perspective view in FIG. 6D, and in a cross-section view in FIG. 6E along the line A-A in FIG. 6D, a trench 610 may be formed through the layer stack of isolation layers 602, metal layers 604, and oxide-semiconductor layers 606. The trench 610 may extend through the layer stack in the z-direction, as well as along the layer stack in the x-direction in the semiconductor device 100.

Moreover, gate openings 612 may be formed around ends of the oxide-semiconductor layers 606 that are exposed through the trench 610. The gate openings 612 may extend from the trench 610 into the ends of the metal layers 604. The gate openings 612 may extend laterally in the x-direction across the ends of the oxide-semiconductor layers 606.

To form the trench 610 and the gate openings 612, one or more etch operations may be performed. For example, a first etch operation may be performed to form the trench 610, and a second etch operation may be performed to etch the ends of the metal layers 604 exposed through the trench 610 to form the gate openings 612.

An etch tool may be used to perform the first etch operation using an anisotropic etch technique such as plasma-based etching. Thus, the first etch operation may primarily include vertical etching that is non-selective in that isolation layers 602, the metal layers 604, and the oxide-semiconductor layers 606 may be etched in the first etch operation.

An etch tool may be used to perform the second etch operation using an isotropic etch technique such as wet etching or gas-based etching. A selective etchant that selectively etches the material of the metal layers 604 with minimal to no etching of the material of the isolation layers 602 and of the material of the oxide-semiconductor layers 606 may be used in the second etch operation. This enables the ends of the metal layers 604 to be laterally etched selectively relative to the isolation layers 602 and the oxide-semiconductor layers 606.

As shown in a perspective view of the semiconductor device 100 in FIG. 6F and in a cross-section view in FIG. 6G along the line A-A in FIG. 6F, a gate dielectric layer 220 may be formed around the ends of oxide-semiconductor layers 606 exposed in the gate openings 612, and the remaining area in the gate openings 612 (as well as the remaining area of the trench 610) may be filled in with material of the word line conductive structures 206 of the memory array 122. As indicated above, the gate openings 612 may extend laterally (e.g., in the x-direction) in the memory array 122. Thus, the word line conductive structures 206 formed in the gate openings 612 extend laterally (e.g., in the x-direction) in the memory array 122. Portions of the word line conductive structures 206 wrapping around two or more sides of the ends of the oxide-semiconductor layer 606 correspond to the gate structures 216 of the memory cell structures 202 of the memory array 122. The ends of the oxide-semiconductor layers 606 coupled to the gate structures 216 correspond to the oxide-semiconductor channel layers 218 of the memory cell structures 202.

A deposition tool may be used to perform a conformal deposition operation such as CVD and/or ALD to conformally deposit the gate dielectric layer 220. A deposition tool may be used to deposit the material of the word line conductive structures 206 (and thus, the material of the gate structures 216) using a PVD technique, a CVD technique, an ALD technique, an electroplating technique, and/or another suitable deposition technique. In some implementations, a planarization tool may be used to perform a planarization operation (e.g., a CMP operation) to planarize the material deposited in the trench 610.

As shown in a perspective view of the semiconductor device 100 in FIG. 6H and in a cross-section view in FIG. 6I along the line A-A in FIG. 6H, portions of the material of the word line conductive structures 206 deposited in the trench 610 may be removed and replaced with an isolation structure 614, which electrically isolates the word line conductive structures 206 coupled to the rows 208 of memory cell structures 202. The isolation structure 614 extends into the area previously corresponding to the trench 610, as well as around ends of the oxide-semiconductor channel layers 218.

In some implementations, an etch tool may be used to perform one or more etch operations to remove the material of the word line conductive structures 206 deposited in the trench 610. For example, an etch tool may be used to perform a wet etch operation to remove the material of the word line conductive structures 206 deposited in the trench 610. As another example, an etch tool may be used to perform a plasma-based etch to remove the material of the word line conductive structures 206 deposited in the trench 610, followed by a wet etch to remove material of the word line conductive structures 206 from the ends of the oxide-semiconductor channel layers 218.

The isolation structure 614 may extend vertically (e.g., in the z-direction) through the memory array 122. The isolation structure 614 may include one or more dielectric materials, such as a silicon oxide (SiOₓ such as SiO₂), a silicon nitride (SiₓN_{y} such as Si₃N₄), a silicon oxynitride (SiON), an aluminum oxide (AlₓO_{y} such as Al₂O₃), a silicon oxycarbide (SiOC), and/or a silicon oxycarbonitride (SiOCN), among other examples.

As shown in a perspective view of the semiconductor device 100 in FIG. 6J and in a cross-section view in FIG. 6K along the line A-A in FIG. 6J, bit line holes 616 may be formed vertically (e.g., in the z-direction) through the isolation structure 614. Ends of the oxide-semiconductor channel layers 218 may be exposed through the bit line holes 616, which enables bit line conductive structures 204 (e.g., vertical bit line conductive structures) to be formed in the bit line holes 616 so that the bit line conductive structures 204 are electrically coupled and/or physically coupled to the ends of the oxide-semiconductor channel layers 218.

To form the bit line holes 616, an etch operation may be performed. An etch tool may be used to perform the etch operation using an anisotropic etch technique such as plasma-based etching. Thus, the etch operation may primarily include vertical etching through the isolation structure 614. In some implementations, a reactive ion etching (RIE) or a deep RIE technique is used to form the bit line holes 616. A deep RIE technique may include multiple etch operations to incrementally increase the depth of the bit line holes 616 with minimal expansion of the lateral width of the bit line holes 616. This enables a high aspect ratio to be achieved for the bit line holes 616. Protective liners may be formed on the sidewalls of the bit line holes 616 between etch operations to protect the sidewalls from etching.

As further shown in FIG. 6J, metal silicide layers 618 may be formed on ends of the oxide-semiconductor channel layers 218 exposed in the bit line holes 616. The metal silicide layers 618 may include a metal silicide material such as titanium silicide (TiSi), ruthenium silicide (RuSi), cobalt silicide (CoSi), and/or another metal silicide material. The metal silicide layers 618 may be included to achieve a low contact resistance between the oxide-semiconductor channel layers 218 and the bit line conductive structures 204 that are to be formed in the bit line holes 616.

The metal silicide layers 618 may be formed by performing a salicidation process. The salicidation process may include using a deposition tool to deposit metal material (e.g., titanium (Ti), ruthenium (Ru), cobalt (Co)) on the exposed ends of the oxide-semiconductor channel layers 218, and performing a thermal operation (e.g., an annealing operation) to cause the metal material to react with the material of the oxide-semiconductor channel layers 218 to form the metal silicide layers 618. Unreacted metal material may be subsequently removed from the exposed ends of the oxide-semiconductor channel layers 218.

As shown in a perspective view of the semiconductor device 100 in FIG. 6L and in a cross-section view in FIG. 6M along the line A-A in FIG. 6L, the bit line conductive structures 204 may be formed in the bit line holes 616 so that the bit line conductive structures 204 are electrically coupled and/or physically coupled to the ends of the oxide-semiconductor channel layers 218. Removing material from the word line conductive structures 206 from the ends of the oxide-semiconductor channel layers 218 (as described in connection with FIGS. 6H and 6I) enables portions of the isolation structure 614 to be positioned between the word line conductive structures 206 and the bit line conductive structures 204 so that the word line conductive structures 206 and the bit line conductive structures 204 are electrically isolated from each other.

A deposition tool may be used to deposit the material of the bit line conductive structures 204 using a CVD technique, a PVD technique, an ALD technique, an electroplating technique, and/or another suitable deposition technique. The material of the bit line conductive structures 204 may be deposited in one or more deposition operations. In some implementations, a planarization tool may be used to perform a planarization operation (e.g., a CMP operation) to planarize the bit line conductive structures 204 to remove excess material from the bit line conductive structures 204.

As shown in a cross-section view in FIG. 6N along the line A-A in FIG. 6L, remaining portions of the metal layers 604 may be removed and replaced with another isolation structure 620. To remove the remaining portions of the metal layers 604, a trench may be formed through the layer stack of isolation layers 602, metal layers 604, and oxide-semiconductor layers 606. The remaining portions of the metal layers 604 may then be removed through the trench. The trench and the areas previously occupied by the remaining portions of the metal layers 604 may be filled in with dielectric material to form the isolation structure 620.

A first etch operation may be performed to form the trench, and a second etch operation may be performed to etch the remaining portions of the metal layers 604 exposed through the trench. An etch tool may be used to perform the first etch operation using an anisotropic etch technique such as plasma-based etching. Thus, the first etch operation may primarily include vertical etching that is non-selective in that the isolation layers 602, the metal layers 604, and the oxide-semiconductor layers 606 may be etched in the first etch operation. An etch tool may be used to perform the second etch operation using an isotropic etch technique such as wet etching or gas-based etching. A selective etchant that selectively etches the material of the metal layers 604 with minimal to no etching of the material of the isolation layers 602 and the oxide-semiconductor layers 606 may be used in the second etch operation. This enables the metal layers 604 to be laterally etched selectively relative to the isolation layers 602 and the oxide-semiconductor layers 606.

A deposition tool may be used to deposit the material of the isolation structure 620 in the areas previously occupied by the remaining portions of the metal layers 604 and in the trench using a PVD technique, an ALD technique, a CVD technique, an epitaxy technique, an oxidation technique, and/or another suitable deposition technique. The material of the isolation structure 620 may be deposited in one or more deposition operations. In some implementations, a planarization tool may be used to perform a planarization operation (e.g., a CMP operation) to planarize the isolation structure 620 after the isolation structure 620 is deposited.

As shown in a perspective view of the semiconductor device 100 in FIG. 6O, and in a cross-section view in FIG. 6P along the line A-A in FIG. 6O, the memory structures 214 of the memory cell structures 202 of the memory array 122 may be formed. To form the memory structures 214, memory structure openings may be formed by removing portions of the oxide-semiconductor layers 606 adjacent to the oxide-semiconductor channel layers 218 and forming the memory structures 214 in the memory structure openings.

To remove the remaining portions of the oxide-semiconductor layers 606 adjacent to the oxide-semiconductor channel layers 218, the material of the isolation structure 620 may be removed from the trench that was formed to remove the remaining portions of the metal layers 604. The portions of the oxide-semiconductor layers 606 adjacent to the oxide-semiconductor channel layers 218 may then be removed through the trench. The memory structures 214 may be deposited through the trench and into the areas previously occupied by the portions of the oxide-semiconductor layers 606 adjacent to the oxide-semiconductor channel layers 218.

A first etch operation may be performed to remove the material of the isolation structure 620 from the trench, and a second etch operation may be performed to etch the portions of the oxide-semiconductor layers 606 adjacent to the oxide-semiconductor channel layers 218 exposed through the trench.

The memory structures 214, may be formed in the memory structure openings so that the memory structures 214 are electrically coupled and/or physically coupled to the oxide-semiconductor channel layers 218 of the transistor structures 212 of the memory cell structures 202. Thus, and as shown in FIG. 6O, the memory structures 214 may be elongated in the y-direction in the semiconductor device. Moreover, and as shown in FIG. 6O, the memory structures 214 may be arranged in a grid in the x-direction (e.g., in rows 208) and in the y-direction (e.g., in columns 210).

As shown in in FIG. 6P, a memory structure 214 may include a capacitor structure that includes electrode layers 622 and 624 that are spaced apart by an insulator layer 626. The electrode layer 622 may be electrically coupled and/or physically coupled to an oxide-semiconductor channel layer 218 of a transistor structure 212. The electrode layers 622 and 624 may each include one or more electrically conductive metals, one or more electrically conductive metal-containing materials, one or more electrically conductive ceramic materials, and/or other types of electrically conductive materials. Examples include tungsten (W), cobalt (Co), ruthenium (Ru), titanium (Ti), aluminum (Al), copper (Cu), gold (Au), titanium nitride (TiN), and/or tantalum nitride (TaN), among other examples. The insulator layer 626 may include one or more electrically insulating materials. In some implementations, the insulator layer 626 includes one or more low-k dielectric materials such as silicon oxide (SiOₓ such as SiO₂). Additionally and/or alternatively, the insulator layer 626 may include one or more high-k dielectric materials such as zirconium oxide (ZrOₓ such as ZrO₂), aluminum oxide (AlₓO_{y} such as Al₂O₃), silicon nitride (SiₓN_{y} such as Si₃N₄), yttrium oxide (YₓO_{y} such as Y₂O₃), lanthanum oxide (LaₓO_{y} such as La₂O₃), and/or hafnium oxide (HfOₓ such as HfO₂), among other examples. In some implementations, the insulator layer 626 is a multiple-layer stack that includes a plurality of dielectric layers. For example, the insulator layer 626 may include a ZrO₂/Al₂O₃/ZrO₂ (ZAZ) layer stack.

Alternatively, a memory structure 214 may include another type of memory structure, such as an MTJ, a resistive memory structure, a phase change memory structure, and/or another type of memory structure.

As indicated above, FIGS. 6A-6P are provided as an example. Other examples may differ from what is described with regard to FIGS. 6A-6P.

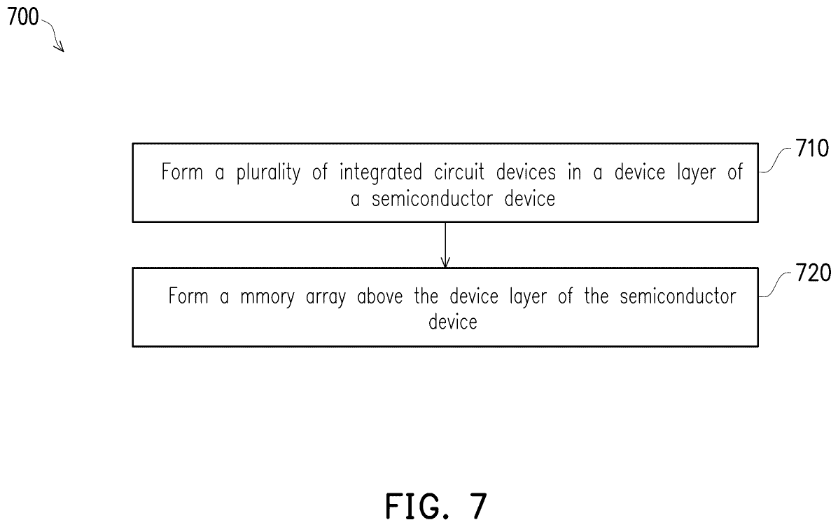

FIG. 7 is a flowchart of an example process 700 associated with forming a semiconductor device described herein. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 7, process 700 may include forming a plurality of integrated circuit devices in a device layer of a semiconductor device (block 710). For example, one or more semiconductor processing tools may be used to form a plurality of integrated circuit devices (e.g., a plurality of integrated circuit devices 108) in a device layer (e.g., a device layer 102) of a semiconductor device (e.g., a semiconductor device 100), as described herein.

As further shown in FIG. 7, process 700 may include forming a memory array above the device layer of the semiconductor device (block 720). For example, one or more semiconductor processing tools may be used to form a memory array (e.g., a memory array 122) above the device layer of the semiconductor device, as described herein. In some implementations, an interconnect layer (e.g., an interconnect layer 104) is formed above the device layer, and the memory array is formed above the interconnect layer. In some implementations, the memory array is formed as part of the interconnect layer.

Process 700 may include additional implementations, such as any single implementation or any combination of implementations described below and/or in connection with one or more other processes described elsewhere herein.

In a first implementation, forming the memory array includes forming an alternating stack of metal layers (e.g., metal layers 402) and oxide-semiconductor layers (e.g., oxide-semiconductor layer 404), removing first portions of the oxide-semiconductor layers to define oxide-semiconductor channel layers (e.g., oxide-semiconductor channel layers 218) of memory cell structures (e.g., memory cell structures of the 202) of the memory array, etching the metal layers between the oxide-semiconductor channel layers to form gate openings (e.g., gate openings 416) between the oxide-semiconductor channel layers, forming gate structures (e.g., gate structures 216) of the memory cell structures in the gate openings, removing second portions of the oxide-semiconductor layers to form memory structure openings (e.g., memory structure openings 418) adjacent to the oxide-semiconductor channel layers, and/or forming memory structures (e.g., memory structures 214) of the memory cell structures in the memory structure openings such that the memory structures are adjacent to the oxide-semiconductor channel layers.

In a second implementation, alone or in combination with the first implementation, the gate openings extend vertically through the alternating stack of metal layers and oxide-semiconductor layers, and process 700 includes forming a plurality of word line conductive structures in the gate openings such that the plurality of word line conductive structures extend vertically in the memory array, wherein portions of a word line conductive structure of the plurality of word line conductive structures correspond to a subset of the gate structures that are coupled to the word line conductive structure.

In a third implementation, alone or in combination with one or more of the first and second implementations, the subset of the gate structures are included in a subset of the memory cell structures that are vertically arranged in the memory array.

In a fourth implementation, alone or in combination with one or more of the first through third implementations, process 700 includes removing third portions of the oxide-semiconductor layers to form bit line conductive structure openings adjacent to the oxide-semiconductor channel layers, and forming bit line conductive structures (e.g., bit line conductive structures 204) of the memory cell structures in the bit line conductive structure openings.

In a fifth implementation, alone or in combination with one or more of the first through fourth implementations, the bit line conductive structures extend laterally in the memory array.

In a sixth implementation, alone or in combination with one or more of the first through fifth implementations, the memory structures are laterally adjacent to first ends of the oxide-semiconductor channel layers, and the bit line conductive structures are laterally adjacent to second ends of the oxide-semiconductor channel layers opposing the first ends.

In a seventh implementation, alone or in combination with one or more of the first through sixth implementations, the oxide-semiconductor layers comprise at least one of indium oxide (InO), indium tungsten oxide (IWO), indium gallium zinc oxide (IGZO), or zinc oxide (ZnO), and the metal layers comprise at least one of titanium nitride (TiN), or tungsten (W).

In an eighth implementation, forming the memory array includes forming a layer stack that includes isolation layers (e.g., isolation layers 602), metal layers (e.g., metal layers 604), and oxide-semiconductor layers (e.g., oxide-semiconductor layers 606), forming a trench (e.g., a trench 610) through the layer stack, etching ends of the metal layers of the layer stack through the trench to define gate openings (e.g., gate openings 612) around ends of the oxide-semiconductor layers, depositing metal material in the gate openings to form gate structures (e.g., gate structures 216) of memory cell structures (e.g., memory cell structures 202) of the memory array, where the gate structures wrap around the ends of the oxide-semiconductor layers, and where the ends of the oxide-semiconductor layers correspond to oxide-semiconductor channel layers (e.g., oxide-semiconductor channel layers 218) of the memory cell structures, removing portions of the oxide-semiconductor layers adjacent to the gate structures to form memory structure openings, and/or forming memory structures (e.g., memory structures 214) of the memory cell structures in the memory structure openings such that the memory structures are adjacent to the oxide-semiconductor channel layers.

In a ninth implementation, alone or in combination with the eighth implementation, depositing the metal material comprises depositing the metal material in the trench, and process 700 includes removing the metal material from the trench, and refilling the trench with dielectric material to form an isolation structure (e.g., an isolation structure 614) in the trench.

In a tenth implementation, alone or in combination with one or more of the eighth or ninth implementations, process 700 includes etching the isolation structure to form holes (e.g., bit line holes 616) in the isolation structure, ends of the oxide-semiconductor channel layers are exposed through the holes, and forming, in the holes, bit line conductive structures (e.g., bit line conductive structures 204), such that the bit line conductive structures are coupled to the ends of the oxide-semiconductor channel layers.

In an eleventh implementation, alone or in combination with one or more of the eighth through tenth implementations, the bit line conductive structures extend in a direction (e.g., a z-direction) that is approximately perpendicular to the device layer.

In a twelfth implementation, alone or in combination with one or more of the first through eleventh implementations, the gate structures are spaced apart from the bit line conductive structures by portions of the isolation structure.

In a thirteenth implementation, alone or in combination with one or more of the first through twelfth implementations, a subset of the gate structures, included in a subset of the memory cell structures that are arranged in a lateral direction (e.g., an x-direction) in the memory array, are coupled together by a word line conductive structure (e.g., a word line conductive structure 206) of the memory array.

In a fourteenth implementation, alone or in combination with one or more of the first through thirteenth implementations, the word line conductive structure extends laterally (e.g., in the x-direction) across the subset of the gate structures.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, memory cell structures of a memory array are formed using materials and processes that are compatible with CMOS integrated circuits that have been formed on a semiconductor device. In particular, the transistor structures of the memory cell structures are formed to include oxide-semiconductor channel layers as opposed to semiconductor channel layers. The oxide-semiconductor channel layers may be formed by lower-temperature processes (e.g., CVD) relative to semiconductor channel layers (e.g., epitaxial growth). Thus, the formation of the oxide-semiconductor channel layers is less likely to degrade and/or damage the layers and/or structures of the CMOS integrated circuits of the semiconductor device. In this way, the semiconductor device may be formed monolithically, meaning the memory array may be formed above the device layer of the semiconductor device in which the CMOS integrated circuits were formed.

As described in greater detail above, some implementations described herein provide a semiconductor device. The semiconductor device includes a device layer. The semiconductor device includes one or more integrated circuit devices in the device layer. The semiconductor device includes a memory array vertically adjacent to the device layer in a first direction. The memory array includes a plurality of memory cell structures. A memory cell structure, of the plurality of memory cell structures, includes a transistor structure that includes an oxide-semiconductor channel layer extending in a second direction approximately perpendicular to the first direction. The memory cell structure includes a memory structure laterally adjacent to the transistor structure in the second direction.

As described in greater detail above, some implementations described herein provide a method. The method includes forming a plurality of integrated circuit devices in a device layer of a semiconductor device. The method includes forming a memory array above the device layer of the semiconductor device. Forming the memory array includes forming an alternating stack of metal layers and oxide-semiconductor layers. Forming the memory array includes removing first portions of the oxide-semiconductor layers to define oxide-semiconductor channel layers of memory cell structures of the memory array. Forming the memory array includes etching the metal layers between the oxide-semiconductor channel layers to form gate openings between the oxide-semiconductor channel layers. Forming the memory array includes forming gate structures of the memory cell structures in the gate openings removing second portions of the oxide-semiconductor layers to form memory structure openings adjacent to the oxide-semiconductor channel layers. Forming the memory array includes forming memory structures of the memory cell structures in the memory structure openings such that the memory structures are adjacent to the oxide-semiconductor channel layers.

As described in greater detail above, some implementations described herein provide a method. The method includes forming a plurality of integrated circuit devices in a device layer of a semiconductor device. The method includes forming a memory array above the device layer of the semiconductor device. Forming the memory array includes forming a layer stack that includes isolation layers, metal layers, and oxide-semiconductor layers. Forming the memory array includes forming a trench through the layer stack etching ends of the metal layers of the layer stack through the trench to define gate openings around ends of the oxide-semiconductor layers. Forming the memory array includes depositing metal material in the gate openings to form gate structures of memory cell structures of the memory array, where the gate structures wrap around the ends of the oxide-semiconductor layers, and where the ends of the oxide-semiconductor layers correspond to oxide-semiconductor channel layers of the memory cell structures. Forming the memory array includes removing portions of the oxide-semiconductor layers adjacent to the gate structures to form memory structure openings. Forming the memory array includes forming memory structures of the memory cell structures in the memory structure openings such that the memory structures are adjacent to the oxide-semiconductor channel layers.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a device layer;
one or more integrated circuit devices in the device layer; and
a memory array, vertically adjacent to the device layer in a first direction, comprising a plurality of memory cell structures,
wherein a memory cell structure, of the plurality of memory cell structures, comprises:
a transistor structure comprising an oxide-semiconductor channel layer extending in a second direction approximately perpendicular to the first direction; and
a memory structure laterally adjacent to the transistor structure in the second direction.

2. The semiconductor device of claim 1, wherein the memory array comprises:
a plurality of bit line conductive structures coupled to the plurality of memory cell structures and extending in a third direction that is approximately perpendicular to the first direction and to the second direction; and
a plurality of word line conductive structures coupled to the plurality of memory cell structures and extending in the first direction.

3. The semiconductor device of claim 2, wherein the transistor structure of the memory cell structure comprises a gate structure wrapping around at least two sides of the oxide-semiconductor channel layer; and
wherein a portion of a word line conductive structure, of the plurality of word line conductive structures, corresponds to the gate structure.

4. The semiconductor device of claim 3, wherein a bit line conductive structure, of the plurality of bit line conductive structures, is coupled to a first end of the oxide-semiconductor channel layer; and
wherein the memory structure is coupled to a second end of the oxide-semiconductor channel layer opposing the first end in the second direction.

5. The semiconductor device of claim 1, wherein the memory array comprises:
a plurality of bit line conductive structures coupled to the plurality of memory cell structures and extending in the first direction; and
a plurality of word line conductive structures coupled to the plurality of memory cell structures and extending in a third direction that is approximately perpendicular to the first direction and to the second direction.

6. The semiconductor device of claim 5, wherein the transistor structure of the memory cell structure comprises a metal gate structure wrapping around at least two sides of the oxide-semiconductor channel layer;
wherein a portion of a word line conductive structure, of the plurality of word line conductive structures, corresponds to the gate structure;
wherein a bit line conductive structure, of the plurality of bit line conductive structures, is coupled to a first end of the oxide-semiconductor channel layer; and
wherein the memory structure comprises a capacitor structure that is coupled to a second end of the oxide-semiconductor channel layer opposing the first end in the second direction.

7. A method, comprising:
forming a plurality of integrated circuit devices in a device layer of a semiconductor device; and
forming a memory array above the device layer of the semiconductor device,
wherein forming the memory array comprises:
forming an alternating stack of metal layers and oxide-semiconductor layers;
removing first portions of the oxide-semiconductor layers to define oxide-semiconductor channel layers of memory cell structures of the memory array;
etching the metal layers between the oxide-semiconductor channel layers to form gate openings between the oxide-semiconductor channel layers;
forming gate structures of the memory cell structures in the gate openings;
removing second portions of the oxide-semiconductor layers to form memory structure openings adjacent to the oxide-semiconductor channel layers; and
forming memory structures of the memory cell structures in the memory structure openings such that the memory structures are adjacent to the oxide-semiconductor channel layers.

8. The method of claim 7, wherein the gate openings extend vertically through the alternating stack of metal layers and oxide-semiconductor layers; and
wherein the method further comprises:
forming a plurality of word line conductive structures in the gate openings such that the plurality of word line conductive structures extend vertically in the memory array,
wherein portions of a word line conductive structure of the plurality of word line conductive structures correspond to a subset of the gate structures that are coupled to the word line conductive structure.

9. The method of claim 8, wherein the subset of the gate structures are included in a subset of the memory cell structures that are vertically arranged in the memory array.

10. The method of claim 7, further comprising:
removing third portions of the oxide-semiconductor layers to form bit line conductive structure openings adjacent to the oxide-semiconductor channel layers; and
forming bit line conductive structures of the memory cell structures in the bit line conductive structure openings.

11. The method of claim 10, wherein the bit line conductive structures extend laterally in the memory array.

12. The method of claim 10, wherein the memory structures are laterally adjacent to first ends of the oxide-semiconductor channel layers; and
wherein the bit line conductive structures are laterally adjacent to second ends of the oxide-semiconductor channel layers opposing the first ends.

13. The method of claim 7, wherein the oxide-semiconductor layers comprise at least one of:
indium oxide (InO),
indium tungsten oxide (IWO),
indium gallium zinc oxide (IGZO), or
zinc oxide (ZnO); and
wherein the metal layers comprise at least one of:
titanium nitride (TiN), or
tungsten (W).

14. A method, comprising:
forming a plurality of integrated circuit devices in a device layer of a semiconductor device; and
forming a memory array above the device layer of the semiconductor device,
wherein forming the memory array comprises:
forming a layer stack that includes isolation layers, metal layers, and oxide-semiconductor layers;
forming a trench through the layer stack;
etching ends of the metal layers of the layer stack through the trench to define gate openings around ends of the oxide-semiconductor layers;
depositing metal material in the gate openings to form gate structures of memory cell structures of the memory array,
wherein the gate structures wrap around the ends of the oxide-semiconductor layers, and
wherein the ends of the oxide-semiconductor layers correspond to oxide-semiconductor channel layers of the memory cell structures;
removing portions of the oxide-semiconductor layers adjacent to the gate structures to form memory structure openings; and
forming memory structures of the memory cell structures in the memory structure openings such that the memory structures are adjacent to the oxide-semiconductor channel layers.

15. The method of claim 14, wherein depositing the metal material comprises:
depositing the metal material in the trench; and
wherein the method further comprises:
removing the metal material from the trench; and
refilling the trench with dielectric material to form an isolation structure in the trench.

16. The method of claim 15, further comprising:
etching the isolation structure to form holes in the isolation structure,
wherein ends of the oxide-semiconductor channel layers are exposed through the holes; and
forming, in the holes, bit line conductive structures, such that the bit line conductive structures are coupled to the ends of the oxide-semiconductor channel layers.

17. The method of claim 16, wherein the bit line conductive structures extend in a direction that is approximately perpendicular to the device layer.

18. The method of claim 16, wherein the gate structures are spaced apart from the bit line conductive structures by portions of the isolation structure.

19. The method of claim 14, wherein a subset of the gate structures, included in a subset of the memory cell structures that are arranged in a lateral direction in the memory array, are coupled together by a word line conductive structure of the memory array.

20. The method of claim 19, wherein the word line conductive structure extends laterally across the subset of the gate structures.
